(19) United States
(12) Patent Application Publication
(10) Pub. No.: US 2026/0040986 A1
(43) Pub. Date: Feb. 5, 2026

(54) INTEGRATED CIRCUIT STRUCTURES AND METHODS OF MANUFACTURING THE SAME

(71) Applicant: Taiwan Semiconductor Manufacturing Company, Ltd., Hsinchu (TW)

(72) Inventors: Gerben DOORNBOS, Kessel-Lo (BE); Marcus Johannes Henricus Van Dal, Linden (BE); Viraj Nilesh Madhiwala, Kessel-Lo (BE); Georgios Vellianitis, Heverlee (BE)

(73) Assignee: Taiwan Semiconductor Manufacturing Company, Ltd., Hsinchu (TW)

(21) Appl. No.: 18/800,136

(22) Filed: Aug. 12, 2024

(30) Foreign Application Priority Data
Aug. 5, 2024 (GR) 20240100555

(51) Int. Cl. H01L 23/00

(52) U.S. Cl. CPC H01L 24/08; H01L 24/80; H01L 2224/08146; H01L 2224/80006; H01L 2224/80895; H01L 2224/80896; H01L 2924/10253; H01L 2924/13067; H01L 2924/13069

(57) ABSTRACT

An integrated circuit structure includes a donor carrier and a device carrier bonded to each other. The donor carrier includes a first bonding structure, a gate pattern disposed on the first bonding structure, a gate dielectric pattern disposed on the gate pattern, a silicon channel pattern disposed on the gate dielectric pattern, and at least one source contact and at least one drain contact disposed separately on the silicon channel pattern. The device carrier includes a device layer, an interconnect structure disposed on the device layer, and a second bonding structure disposed on the interconnect structure. The donor carrier is bonded to the device carrier through the first bonding structure and the second bonding structure.

### CROSS-REFERENCE TO RELATED APPLICATION

This application claims the priority benefit of Greece application serial no. 20240100555, filed on Aug. 5, 2024. The entirety of the above-mentioned patent application is hereby incorporated by reference herein and made a part of this specification.

### BACKGROUND

The semiconductor integrated circuit (IC) industry has experienced exponential growth. Technological advances in IC materials and design have produced generations of ICs where each generation has smaller and more complex circuits than the previous generation. In the course of the IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Although the existing integrated circuit structures have been generally adequate for their intended purposes, they have not been entirely satisfactory in every aspect. For example, the heat dissipation is a challenge in a variety of integrated circuit structures.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, 7A, 7B, 8A, 8B, 9A, 9B, 10A, 10B, 10C, 11A, 11B, 11C, 12A, 12B, 13A, 13B, 14A, 14B, 15A, 15B, 16A, 16B, 17A, 17B, 18A, 18B, 18C, 19A, 19B, 19C, 20A, 20B, 21A, 21B, 22A and 22B illustrate varying views of manufacturing an integrated circuit structure in accordance with some embodiments.

FIGS. 23, 24, 25, 26, 27A, 27B, 28A and 28B illustrate varying views of manufacturing an integrated circuit structure in accordance with some embodiments.

FIGS. 29, 30, 31, 32A, 32B, 32C, 33A, 33B, 34, 35A, 35B and 36 illustrate varying views of manufacturing an integrated circuit structure in accordance with some embodiments.

FIGS. 37, 38, 39A, 39B, 40, 41, 42, 43, 44, 45A, 45B, 46A, 46B, 47A, 47B, 48A, 48B, 48C, 49A, 49B, 49C, 50A, 50B, 51A, 51B, 52A, 52B, 53A, 53B, 54A, 54B, 55A, 55B, 56A, 56B, 56C, 57A, 57B, 57C, 58A and 58B illustrate varying views of manufacturing an integrated circuit structure in accordance with some embodiments.

FIGS. 59A and 59B illustrate varying views of manufacturing an integrated circuit structure in accordance with some embodiments.

FIGS. 60A and 60B illustrate varying views of manufacturing an integrated circuit structure in accordance with some embodiments.

FIGS. 61A and 61B illustrate varying views of manufacturing an integrated circuit structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Unless otherwise indicated, the same reference number in different figures throughout the specification refers to the same or similar element made by the same or a similar process using the same or similar materials.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Elements with the same reference numerals refer to the same element, and are presumed to have the same material composition and the same thickness range unless expressly indicated otherwise.

The present disclosure is directed to integrated circuit structures and manufacturing methods thereof. In the integrated circuit structure of the disclosure, a silicon thin film transistor (TFT) and a field effect transistor (FET) are manufactured on different substrates and then bonded together. By such method, a back-gated silicon thin film transistor can be formed with a smaller device footprint and can be easily manufactured in a back-end of line (BEOL). In the present disclosure, the gate width of the TFT can be adjusted to provide more process flexibility.

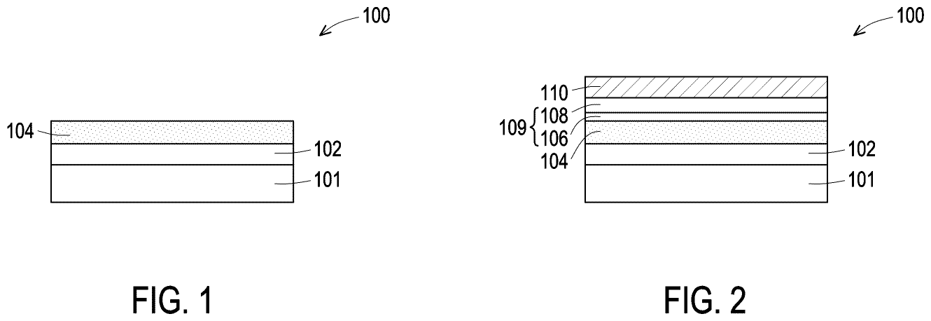

FIGS. 1, 2, 3, 4, 5, 6, 7A, 7B, 8A, 8B, 9A, 9B, 10A, 10B, 10C, 11A, 11B, 11C, 12A, 12B, 13A, 13B, 14A, 14B, 15A, 15B, 16A, 16B, 17A, 17B, 18A, 18B, 18C, 19A, 19B, 19C, 20A, 20B, 21A, 21B, 22A and 22B illustrate varying views of manufacturing an integrated circuit structure in accordance with some embodiments. It is understood that the disclosure is not limited by the method described below. Additional operations can be provided before, during, and/or after the method and some of the operations described below can be replaced or eliminated, for additional embodiments of the methods. Although FIG. 1 to FIG. 22B are described in relation to a method, it is appreciated that the structures disclosed in FIG. 1 to FIG. 22B are not limited to such a method, but instead may stand alone as structures independent of the method.

FIG. 1 to FIG. 3 illustrate providing a donor carrier 100, in accordance with some embodiments. The donor carrier 100 may be in form of a circular-like wafer, a rectangular-like wafer or a sliced piece of a wafer. First, as shown in FIG. 1, a substrate 101 is provided. The substrate 101 may be a blanket wafer such as a silicon wafer. In some embodiments, the substrate 101 may be a Si(001) wafer having a thickness of about 0.5-1 mm. The substrate 101 is configured to manufacture a silicon thin film transistor (TFT) thereon, but the substrate 101 will be removed after the bonding process (which will be described in detail in FIG. 6).

In some embodiments, an etch stop layer 102 and a channel layer 104 are sequentially formed on the substrate 101. The etch stop layer 104 may include SiGe having a germanium content of about 10-40 at % (e.g., 25 at %). The etch stop layer 104 has a thickness of about 20-200 nm (e.g., 80 nm). The channel layer 104 may include crystalline silicon and serve as a TFT channel. The silicon channel layer 104 may contain impurities that act as dopants, e.g., B, P or As, with a concentration of about 10¹⁵-10¹⁹ atoms/cm³. Although Si is used as primary example for channel layer 104 in the following, other suitable semiconductors are within the scope of this invention. These comprise group-IV materials such as SiGe (e.g., having a germanium content substantially different from the germanium content of etch stop layer 104), pure Ge, GeSn, group III-IV compounds such as InAs, GaAs or InGaAs, or nitride compounds such as InN or GaN.

In other embodiments, hydrogen atoms are implanted into the substrate 101, so as to cause a layer of microbubbles in a doping section of the substrate 101. Later in the process, as part of the substrate removal, the substrate 101 is cleaved at the layer of the microbubbles, utilizing the layer as a cleaved surface. The hydrogen implantation is optional and may be omitted as needed.

Thereafter, as shown in FIG. 2, an interfacial layer 106 is formed on the silicon channel layer 104. In some embodiments, the interfacial layer 106 includes silicon oxide and has a thickness of about 0.2-2 nm (e.g., 1 nm). The interfacial layer (IL) 104 may be a chemical oxide, formed from a chemical reaction at the silicon surface, e.g., with ozone (O₃) in combination with HF and/or HCl. The interfacial layer 106 may be a thermal oxide, by rapid thermal annealing (RTA) in an oxygen-containing ambient, or by in situ steam generation (ISSG). The interfacial layer 106 may be a deposited oxide formed by atomic layer deposition (ALD) or chemical vapor deposition (CVD). The chemical oxide (<100° C.) and ALD oxide (<300° C.) may be preferred in the disclosure owing to their low process temperature. After the interfacial layer 106 is formed, an annealing process may be performed in hydrogen-containing ambient or H-plasma to cure defects (e.g., passivate dangling bonds at Si/IL interface).

Thereafter, a high-k (HK) layer 108 is formed on the interfacial layer 106. In some embodiments, the high-k layer 108 includes a dielectric having a dielectric constant greater than 10 and has a thickness of about 1-8 nm (e.g., 2 nm). The high-k layer 108 may be formed by ALD. The high-k layer 108 includes HfO₂, Al₂O₃, ZrO₂, HfZrOₓ, HfAlOₓ, HfSiOₓ, La₂O₃, TiO₂ or a combination thereof. After the high-k layer 108 is formed, an annealing process may be performed in hydrogen-containing, oxygen-containing or nitrogen-containing ambient to cure bulk defects in the high-k layer 108. The interfacial layer 106 and the high-k layer 108 are collectively called a “gate dielectric layer 109” in some examples.

Afterwards, a gate layer 110 is formed on the high-k layer 108. In some embodiments, the gate layer 110 includes Ti, TiN, Ta, TaN, TiAl, W or a combination thereof and has a thickness of about 4-40 nm (e.g., 20 nm). For example, the gate layer 110 may be a layered stack, e.g., TiN/TiAl/TaN, or TiN/W. For example, the gate layer 110 may include a work function metal (e.g., TiN) and a filling metal (e.g., W). The gate layer 110 may be formed by ALD or PVD.

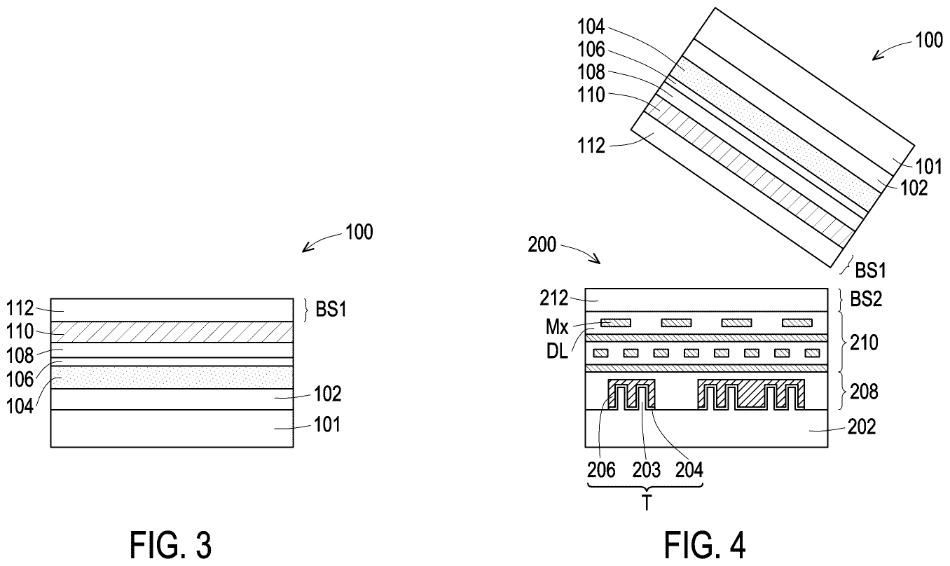

Afterwards, as shown in FIG. 3, a bonding structure BS1 is formed on top of the gate layer 110. In some embodiments, the bonding structure BS1 is a bonding dielectric layer 112. The bonding dielectric layer 112 includes silicon oxide, silicon nitride, SiCN, or a combination thereof. The bonding dielectric layer 112 has a thickness of about 10-100 nm (e.g., 40 nm). A donor carrier 100 is thus obtained. In some embodiments, the donor carrier 100 includes, from bottom to top, a substrate 101, an etch stop layer 102, a silicon channel layer 104, an interfacial layer 106, a high-k layer 108, a gate layer 110 and a bonding structure BS1.

FIG. 4 illustrates providing a device carrier 200, in accordance with some embodiments. The device carrier 200 may be in form of a circular-like wafer, a rectangular-like wafer or a sliced piece of a wafer. First, a substrate 202 is provided. The substrate 202 may be a semiconductor wafer such as a silicon wafer. The substrate 202 is configured to manufacture a field effect transistor (FET) thereon. A front-end of line (FEOL) 208 and a back-end of line (BEOL) 210 are sequentially formed on the substrate 202 and electrically connected to each other. In some embodiments, the FEOL 208 includes devices T such as FinFET devices. In each device T, multiple fins 203 are protruded from the substrate 202, a gate dielectric layer 204 (e.g., an interfacial layer and a high-k layer) is disposed on surfaces of the fins, and a gate layer 206 (e.g., a metal gate) is disposed on the gate dielectric layer 204. Each device T may include source and drain regions (not shown) in the fins 203 beside the gate layer 206. In other embodiments, the devices T may include planar devices, gate all around (GAA) devices, or nano-sheet (NS) devices instead of FinFET devices. The FEOL 208 is referred to as a “device layer” in some examples. In some embodiments, the BEOL 210 includes an interconnect structure electrically connected to the devices T. The BEOL 210 includes metal features embedded in dielectric layers DL. The BEOL 210 is referred to as a “lower interconnect structure” in some examples. The metal features include metal lines and metal vias electrically connected to each other. The metal features include Cu, Al, Co, Ru, Cr, W, Ti, Ta, TiN, TaN, the like or a combination thereof. The dielectric layers include dielectric materials and etch stop materials between adjacent dielectric materials. The dielectric material includes silicon oxide, silicon oxynitride, silicon oxycarbide or a low-k material having a dielectric constant less than 3.5 or 2.5, and the etch stop material includes aluminum nitride, aluminum oxide, aluminum oxynitride, silicon nitride, silicon carbide, silicon carbon nitride, or a combination thereof. In FIG. 4, four metal line levels are shown, inter-level metal vias are not shown, and top metal lines Mₓ are labelled for further illustration purpose. In some embodiments, the top metal lines Mₓ are covered by the top dielectric layer DL. The number of metal line levels is not limited by the disclosure. For example, the number of metal line levels ranges from 1 to 15, such as from 4 to 6.

Thereafter, a bonding structure BS2 is formed on top of the BEOL 210. In some embodiments, the bonding structure BS2 is a bonding dielectric layer 212. The bonding dielectric layer 212 includes silicon oxide, silicon nitride, SiCN, or a combination thereof. The bonding dielectric layer 212 has a thickness of about 10-10 0nm (e.g., 40 nm). In some embodiments, the bonding dielectric layer 112 and the bonding dielectric layer 212 include the same material, such as silicon oxide. In some embodiments, the bonding dielectric layer 112 and the bonding dielectric layer 212 include different materials, one of which is silicon oxide and the other is silicon nitride. A device carrier 200 is thus obtained. In some embodiments, the device carrier 200 includes, from bottom to top, a substrate 202, a front-end of line (FEOL) 208, a back-end of line (BEOL) 210 and a bonding structure BS2.

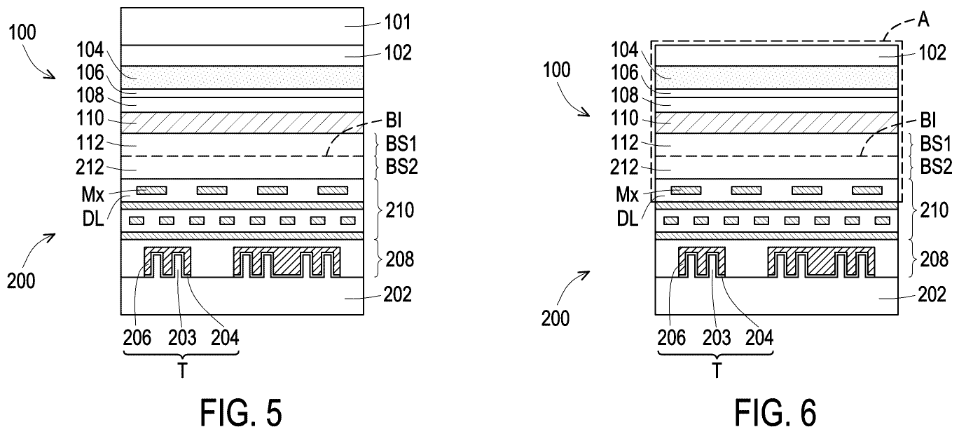

FIG. 4 and FIG. 5 illustrate bonding the donor carrier 100 to the device carrier 200, in accordance with some embodiments. In some embodiments, the donor carrier 100 is turned over and bonded to the device carrier 200 through the bonding structure BS1 (e.g., the bonding dielectric layer 112) and the bonding structure BS2 (e.g., the bonding dielectric layer 212). The bonding structure BS1 and the bonding structure BS2 collectively constitute a “composite bonding structure”. The bonding interface BI between the bonding dielectric layer 112 and the bonding dielectric layer 212 may or may not be detectible. Such homogeneous dielectric-to-dielectric bonding between dielectric materials is referred to as a “fusion bonding” in some examples. In some embodiments, a post-bond curing annealing is performed to improve the bonding strength between the bonding structure BS1 and the bonding structure BS2. Other approaches include a metal-to-metal bonding and a hybrid bonding which will be described in later embodiments.

FIG. 6 illustrates removing the substrate 101, in accordance with some embodiments. Specifically, the substrate 101 is removed from the donor carrier 100. In some embodiments, a grinding process is performed to the substrate 101 until about 100 um of silicon remains. The remaining silicon is removed by an etching process (e.g., a wet or dry etching) by using the etch stop layer 104 as an etching stop layer. In other embodiments, a short thermal annealing process is performed, and the donor carrier 100 “cracks” at the layer of microbubbles caused by hydrogen implantation. From here on, a local region A of a simplified stack will be shown for clarity.

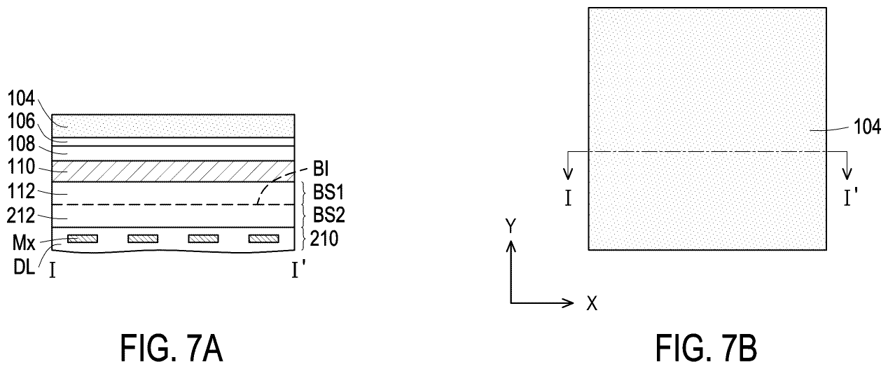

FIG. 7A and FIG. 7B illustrate removing the etch stop layer 104, in accordance with some embodiments. FIG. 7A may be a cross-sectional view taken along the line I-I′ of the top view of FIG. 7B. The etch stop layer 104 is removed by an etching process (e.g., a wet or dry etching), using the silicon channel layer 104 as an etching stop layer. Upon the removing process, the silicon channel layer 104 of the donor carrier 100 is exposed.

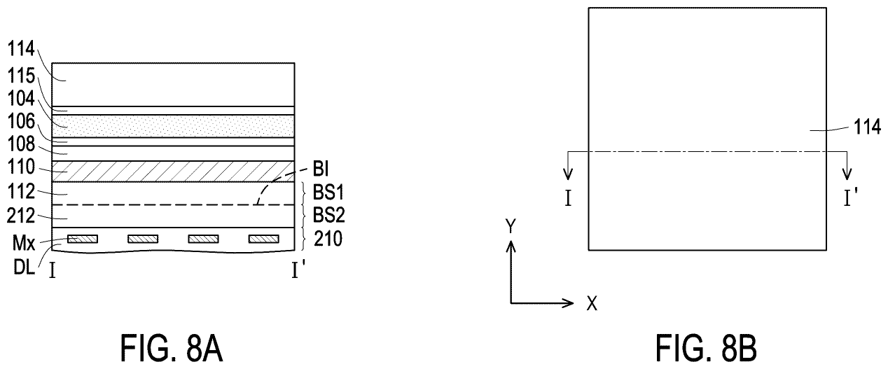

FIG. 8A and FIG. 8B illustrate forming an interfacial layer 115 and a dielectric layer 114, in accordance with some embodiments. FIG. 8A may be a cross-sectional view taken along the line I-I′ of the top view of FIG. 8B. As shown in FIG. 8A, an interfacial layer 115 is formed on the silicon channel layer 104. In some embodiments, the interfacial layer 115 includes silicon oxide and has a thickness of about 1-8 nm (e.g., 2 nm). The interfacial layer 115 may be a chemical oxide, formed from a chemical reaction at the silicon surface, e.g., with ozone (O₃) in combination with HF and/or HCl. The interfacial layer 115 may be a thermal oxide, by rapid thermal annealing (RTA) in an oxygen-containing ambient, or by in situ steam generation (ISSG). The interfacial layer 115 may be a deposited oxide formed by atomic layer deposition (ALD) or chemical vapor deposition (CVD). The chemical oxide (<100° C.) and ALD oxide (<300° C.) may be preferred in the disclosure owing to their low process temperature. The interfacial layer 115 is formed to passivate the top surface of the silicon channel layer 104. After the interfacial layer 106 is formed, an annealing process may be performed in hydrogen-containing ambient or H-plasma to cure defects (e.g., passivate dangling bonds at Si/IL interface). The interfacial layer 115 may be optional and may be omitted as needed.

Thereafter, a dielectric layer 114 is formed on the interfacial layer 115. In some embodiments, the dielectric layer 114 includes silicon oxide and has a thickness of about 40-400 nm (e.g., 100 nm). Other dielectric materials may be applicable. The dielectric layer 114 may be formed by ALD or CVD.

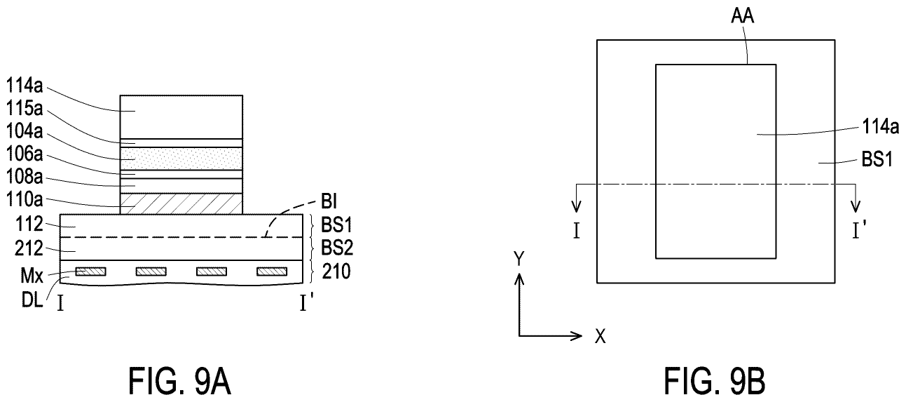

FIG. 9A and FIG. 9B illustrate forming a TFT stack in an active area AA, in accordance with some embodiments. FIG. 9A may be a cross-sectional view taken along the line I-I′ of the top view of FIG. 9B. As shown in FIG. 9A, a patterning process is performed to pattern the layered structure, so as to form a stack including, from bottom to top, a gate pattern 110a, a high-k pattern 108a, an interfacial pattern 106a, a silicon channel pattern 104a, an interfacial pattern 115a and a dielectric pattern 114a. The patterning process includes photolithography and etching processes. The dielectric pattern 114a acts as a hard mask to protect the underlying silicon channel pattern 104a. In some embodiments, as shown in FIG. 9B, the stack has a dimension of about 45 nm to 40 um in the X-direction and a dimension of about 40 nm to 40 um in the Y-direction. One or more TFTs can be formed in one active area AA along the X-direction.

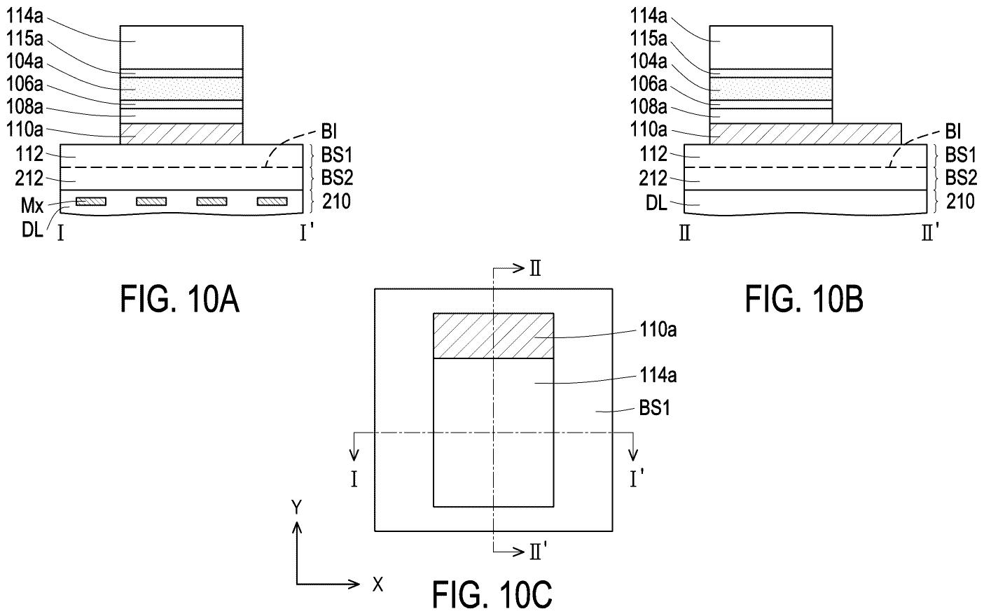

FIG. 10A, FIG. 10B and FIG. 10C illustrate patterning the TFT stack, in accordance with some embodiments. FIG. 10A may be a cross-sectional view taken along the line I-I′ of the top view of FIG. 10C, and FIG. 10B may be a cross-sectional view taken along the line II-II' of the top view of FIG. 10C. As shown in FIG. 10B, a patterning process is performed to pattern the stack, until a portion of the gate pattern 110a is exposed. The patterning process includes photolithography and etching processes. Specifically, the dielectric pattern 114a, the interfacial pattern 115a, the silicon channel pattern 104a, the interfacial pattern 106a and the high-k pattern 108a are sequentially patterned and partially removed, until a portion of the gate pattern 110a is exposed. In some embodiments, as shown in FIG. 10B, the first sidewall (e.g., left sidewall) of the gate pattern 110a is flush with the first sidewall (e.g., left sidewall) of the silicon channel pattern 104a, while the second sidewall (e.g., right sidewall) of the gate pattern 110a is protruded from the second sidewall (e.g., right sidewall) of the silicon channel pattern 104a. In some embodiments, as shown in FIG. 10C, the exposed gate pattern 110a has a dimension of about 45 nm to 40 um in X-direction and a dimension of about 20 nm to 100 nm in Y-direction.

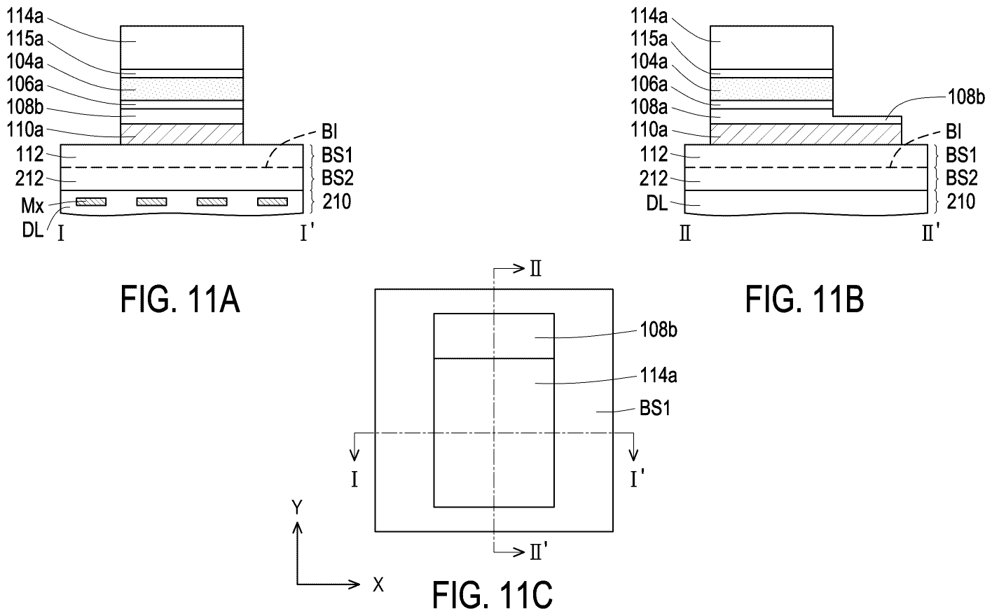

Alternatively, the patterning process of FIG. 10A to FIG. 10C may not etch through the high-k pattern 108a, so a thin high-k pattern 108b remains on the gate pattern 110a, as shown in FIG. 11A, FIG. 11B and FIG. 11C. The thin high-k pattern 108b may cover and protect the underlying gate pattern 110a from being damaged in the subsequent processes.

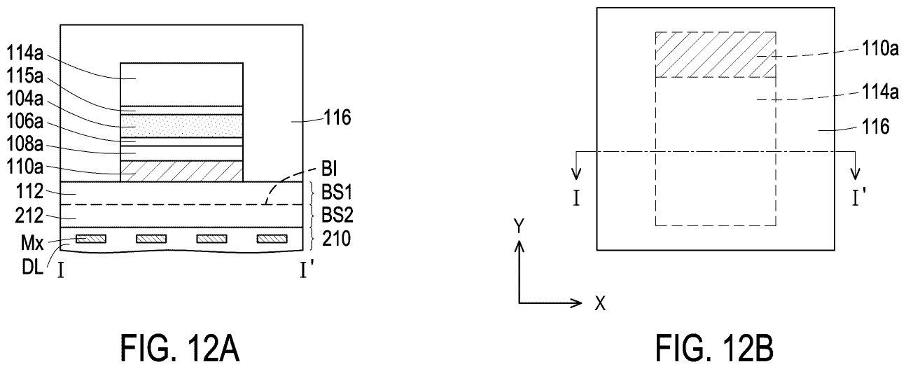

FIG. 12A and FIG. 12B illustrate forming a dielectric layer 116, in accordance with some embodiments. FIG. 12A may be a cross-sectional view taken along the line I-I′ of the top view of FIG. 12B. As shown in FIG. 12A, a dielectric layer 116 is formed to cover the patterned stack. In some embodiments, the dielectric layer 116 includes silicon oxide and has a thickness of about 40-400 nm (e.g., 100 nm). Other dielectric materials may be applicable. The dielectric layer 116 may be formed by ALD or CVD. A planarization process such as chemical mechanical polishing (CMP) or etching back may be performed to planarize the top surface of the dielectric layer 116.

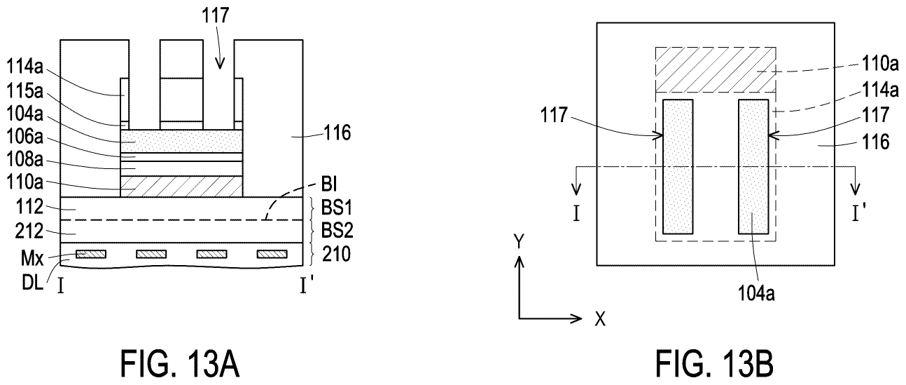

FIG. 13A and FIG. 13B illustrate forming openings 117 in the patterned TFT stack, in accordance with some embodiments. FIG. 13A may be a cross-sectional view taken along the line I-I′ of the top view of FIG. 13B. As shown in FIG. 13B, a patterning process is performed to the dielectric layer 116, the dielectric pattern 114a and the interfacial pattern 115a, so as to form openings 117 exposing the silicon channel pattern 104a. The patterning process includes photolithography and etching processes. As shown in FIG. 13B, each opening 117 has a strip-like shape. The openings 117 may be referred to as “source/drain openings” in some examples.

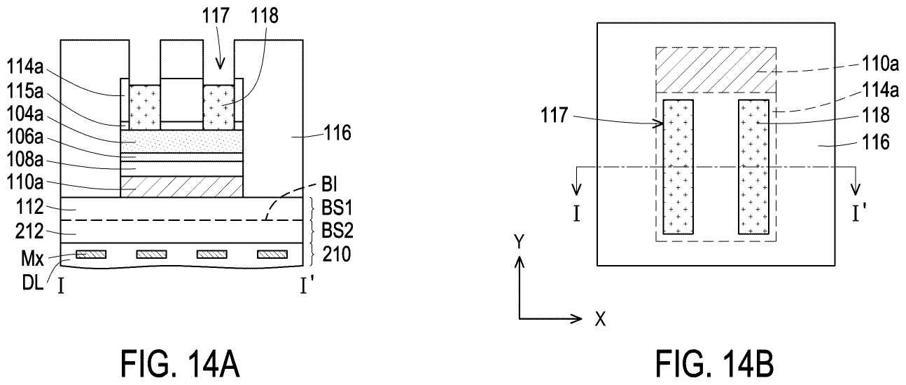

FIG. 14A and FIG. 14B illustrate forming epitaxial layers 118, in accordance with some embodiments. FIG. 14A may be a cross-sectional view taken along the line I-I′ of the top view of FIG. 14B. As shown in FIG. 14A, epitaxial layers 118 are selectively grown from the silicon channel layer 104a in the openings 117. In some embodiments, the epitaxial layers 118 may not completely fill the openings 117. The epitaxial layers 118 may include Si:P, with phosphorous concentration of about 10²⁰-10²¹ atoms/cm³ for an N-type device. The epitaxial layers 118 may include SiGe: B, with a boron concentration of about 10²⁰-10²¹ atoms/cm³ and a germanium content of about 1-50 at % for a P-type device. Other epitaxial materials for the epitaxial layers 118 may be applicable. In some embodiments, the epitaxial layers 118 have a thickness of about 5-40 nm (e.g., 20 nm). In some embodiments, the epitaxial layers 118 may be formed by an in situ doped selective epitaxial process. In other embodiments, the epitaxial layers 118 may be formed by epitaxial growth, followed by ion implantation and annealing. The epitaxial layers 118 may be referred to as “source/drain epitaxial layers” or “source/drain layers” in some examples.

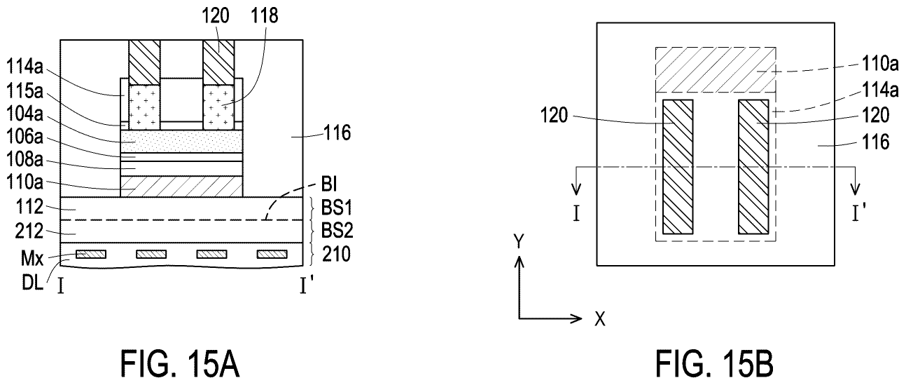

FIG. 15A and FIG. 15B illustrate forming metal patterns 120, in accordance with some embodiments. FIG. 15A may be a cross-sectional view taken along the line I-I′ of the top view of FIG. 15B. As shown in FIG. 15A, metal patterns 120 are formed over the epitaxial layers 118 in the openings 117. The metal patterns 120 include TiN, W, Ta, TaN, Cu, or a combination thereof, so as to reduce access resistance. In some embodiments, the metal patterns 120 are formed by ALD or PVD, followed by CMP. The metal patterns 120 may be referred to as “source/drain metal patterns” or “source/drain contacts” in some examples. The metal patterns 120 may be optional and may be omitted as needed.

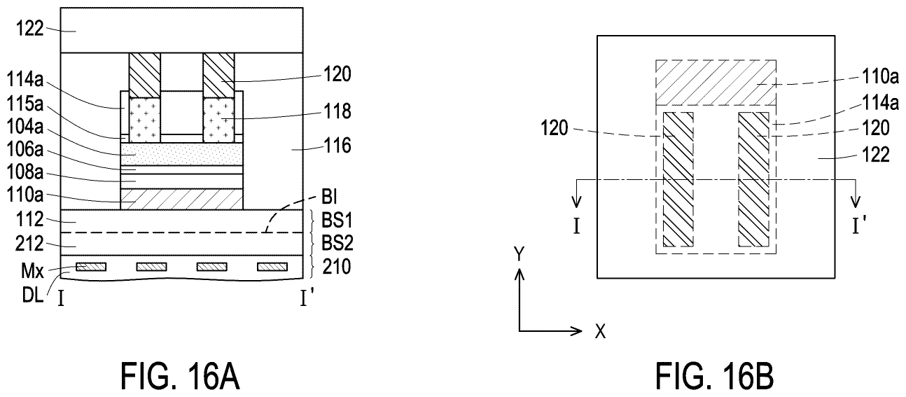

FIG. 16A and FIG. 16B illustrate forming a dielectric layer 122, in accordance with some embodiments. FIG. 16A may be a cross-sectional view taken along the line I-I′ of the top view of FIG. 16B. As shown in FIG. 16A, a dielectric layer 122 is formed to cover the dielectric layer 116 and the metal patterns 120. In some embodiments, the dielectric layer 122 includes silicon oxide and has a thickness of about 20-200 nm (e.g., 100 nm). Other dielectric materials may be applicable. The dielectric layer 122 may be formed by ALD or CVD.

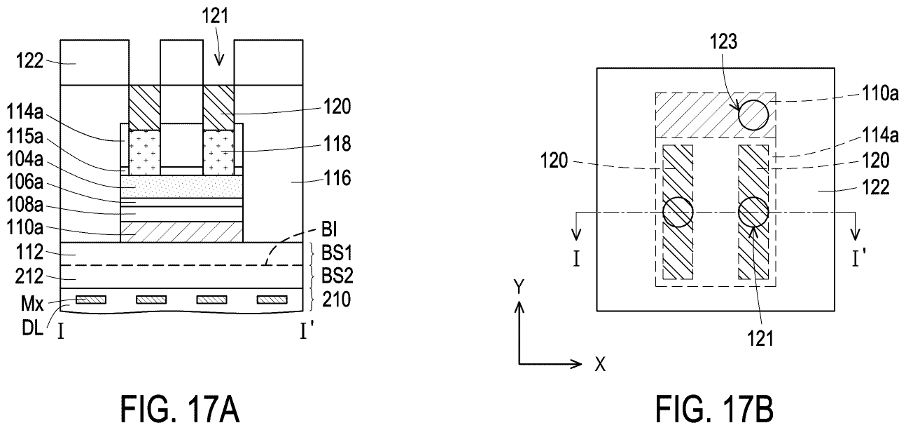

FIG. 17A and FIG. 17B illustrate forming openings 121 and 123 in the dielectric layer 122, in accordance with some embodiments. FIG. 17A may be a cross-sectional view taken along the line I-I′ of the top view of FIG. 17B. As shown in FIG. 17A, a patterning process is performed to the dielectric layer 122 and the dielectric layer 116, so as to form openings 121 exposing the metal patterns 120 and an opening 123 exposing the gate pattern 110a. The patterning process includes photolithography and etching processes. As shown in FIG. 17B, each of the openings 121 and 123 has a circle-like shape. In other embodiments, each of the openings 121 and 123 has a square or rectangular shape.

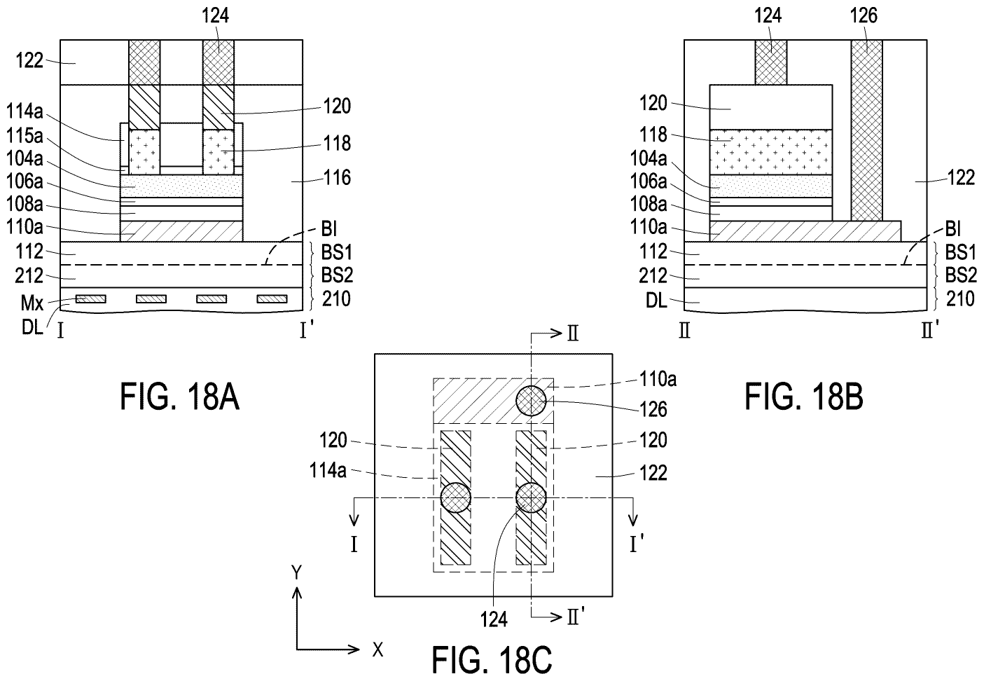

FIG. 18A, FIG. 18A and FIG. 18C illustrate forming metal vias 124 and 126, in accordance with some embodiments. FIG. 18A may be a cross-sectional view taken along the line I-I′ of the top view of FIG. 18C, and FIG. 18B may be a cross-sectional view taken along the line II-II′ of the top view of FIG. 18C. As shown in FIG. 18A, metal vias 124 are formed over the metal patterns 120, and a metal via 126 is formed on the gate pattern 110a. The width of the via 126 may be the same as or different from (greater than, or smaller than) the width of the metal vias 124. The metal vias 124 and 126 include TiN, W, Ta, TaN, Cu, or a combination thereof. In some embodiments, the metal vias 124 and 126 are formed by ALD or PVD, followed by CMP. In other embodiments, the metal vias 124 and 126 are formed by a dual damascene process with the next metal level Mₓ₊₁.

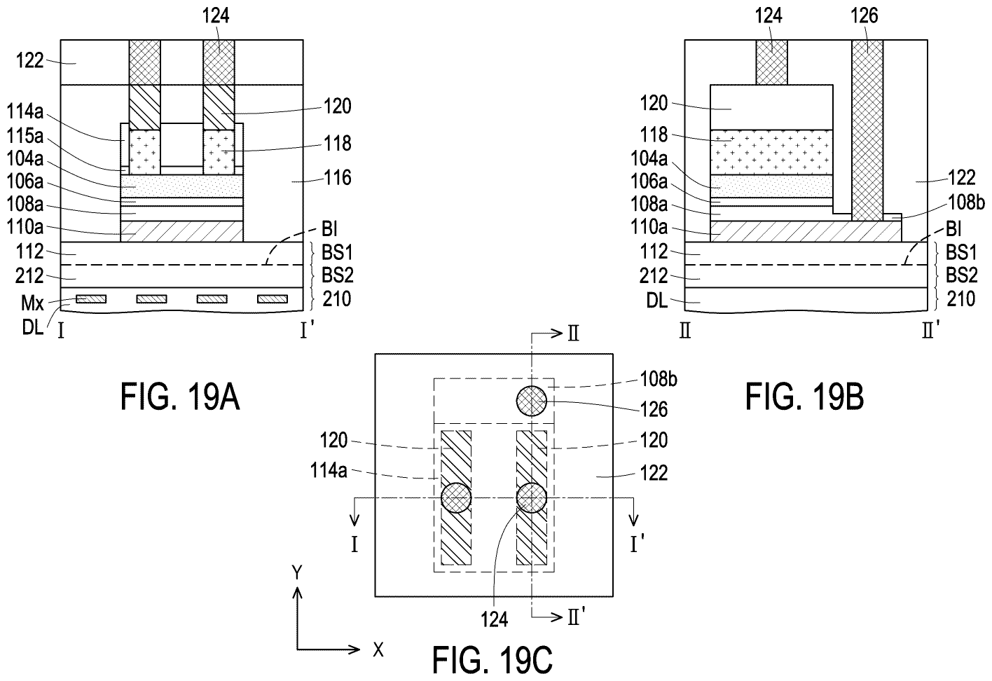

FIG. 19A, FIG. 19A and FIG. 19C illustrate other embodiments of FIG. 18A, FIG. 18A and FIG. 18C. FIG. 19A may be a cross-sectional view taken along the line I-I′ of the top view of FIG. 19C, and FIG. 19B may be a cross-sectional view taken along the line II-II′ of the top view of FIG. 19C. Specifically, in the structure of FIG. 19A, FIG. 19B and FIG. 19C, a thin high-k pattern 108b remains on the gate pattern 110a, and the metal via 126 penetrates through the thin high-k pattern 108b and is landed on the gate pattern 110a.

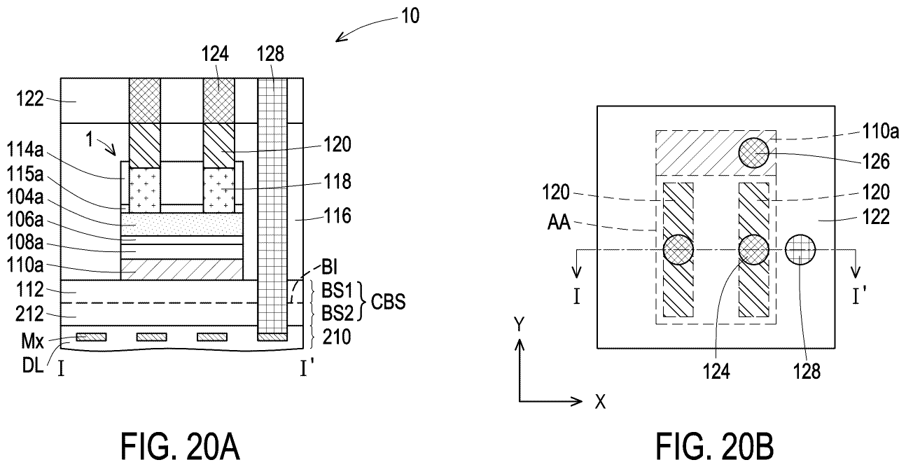

FIG. 20A and FIG. 20B illustrate forming a deep via 128, in accordance with some embodiments. FIG. 20A may be a cross-sectional view taken along the line I-I′ of the top view of FIG. 20B. As shown in FIG. 20A, a patterning process is performed to the dielectric layer 122, the dielectric layer 116, the bonding structure BS1 and the bonding structure BS2, so as to form a deep opening exposing one of the top metal lines Mₓ. The patterning process includes photolithography and etching processes. The deep opening may have a circle-like shape, a square shape or a rectangular shape. Thereafter, a deep via 128 is formed in the deep opening. The width of the deep via 128 may be the same as or different from (greater than, or smaller than) the width of the metal vias 124. The deep via 128 includes TiN, W, Ta, TaN, Cu, or a combination thereof. In some embodiments, the deep via 128 is formed by ALD or PVD, followed by CMP. In other embodiments, the deep via 128 is formed by a dual damascene process with the next metal level Mₓ₊₁. In some embodiments, the deep via 128 is formed together with the vias 124 and 126. An integrated circuit structure 10 of some embodiments of the disclosure is thus completed.

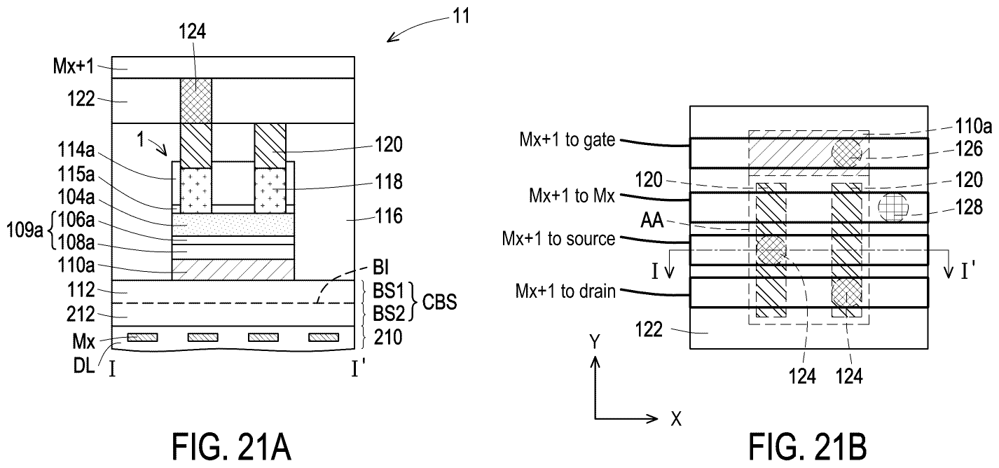

FIG. 21A and FIG. 21B illustrate an integrated circuit structure of other embodiments of the disclosure. FIG. 21A may be a cross-sectional view taken along the line I-I′ of the top view of FIG. 21B. By arranging the positions of metal vias 124, 126 and 128, different metal lines Mₓ₊₁ are formed over and electrically connected to different TFT terminals, or the top metal line Mₓ. The metal lines Mₓ₊₁ may be referred to as an “upper interconnect structure” in some examples. As shown in FIG. 21B, one metal line Mₓ₊₁ is electrically connected to a gate of a TFT through a metal via 126, one metal line Mₓ₊₁ is electrically connected to a top metal line Mₓ through a metal via 128, one metal line Mₓ₊₁ is electrically connected to a source of the TFT through a metal via 124, and one metal line Mₓ₊₁ is electrically connected to a drain of the TFT through another metal via 124. In some embodiments, as shown in FIG. 21B, multiple metal lines Mₓ₊₁ on the donor carrier 100 and the top metal lines Mₓ of the device carrier 200 have alternating X-Y directions. Three features (e.g., metal lines Mₓ₊₁, the silicon channel pattern 104a, top metal lines Mₓ) may be 90 degrees rotated. An integrated circuit structure 11 of some embodiments of the disclosure is thus completed.

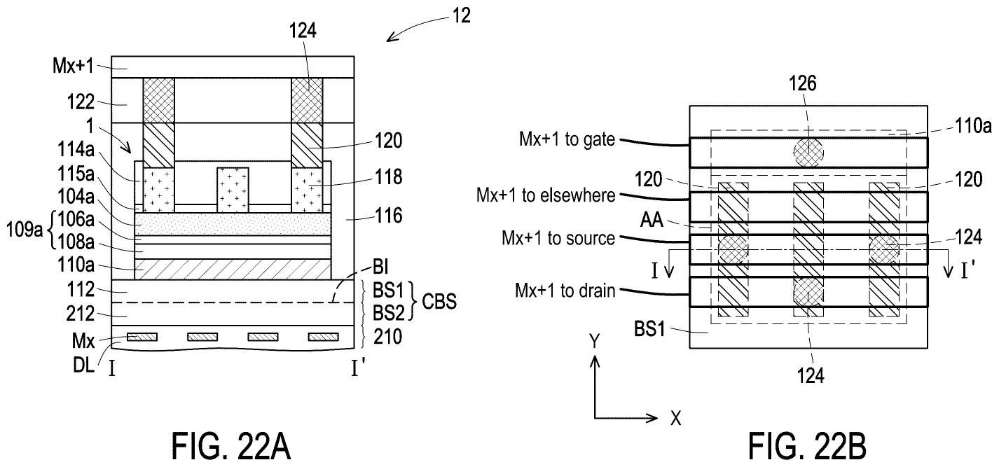

FIG. 22A and FIG. 22B illustrate an integrated circuit structure of other embodiments of the disclosure. FIG. 22A may be a cross-sectional view taken along the line I-I′ of the top view of FIG. 22B. In another embodiment, an active arca AA has at least one source contact and/or at least one drain contact. As shown in FIG. 22A, the integrated circuit structure 12 includes one gate contact, two source contacts and one drain contact, providing a device having 2× effective width, or “two fingers”. More BEOL layers may be added to the metal line Mₓ₊₁ as needed.

In the above embodiments, a donor carrier including at least one TFT device and a device carrier including at least one FET device are bonded by a dielectric fusion bonding, but the disclosure is not limited thereto. In other embodiments, a donor carrier including at least one TFT device and a device carrier including at least one FET device may be bonded through a metal eutectic bonding.

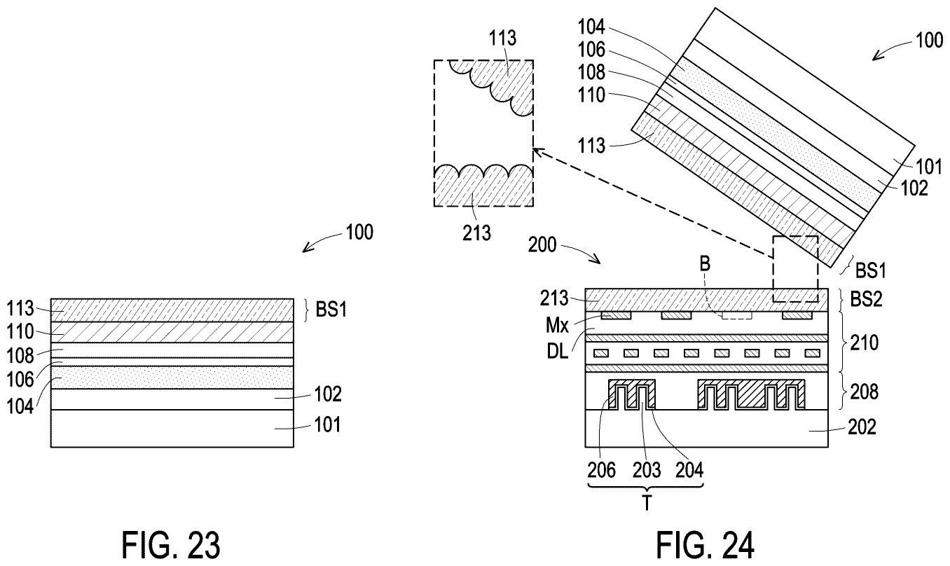

FIGS. 23, 24, 25, 26, 27A, 27B, 28A and 28B illustrate varying views of manufacturing an integrated circuit structure in accordance with some embodiments. It is understood that the disclosure is not limited by the method described below. Additional operations can be provided before, during, and/or after the method and some of the operations described below can be replaced or eliminated, for additional embodiments of the methods. Although FIG. 23 to FIG. 28B are described in relation to a method, it is appreciated that the structures disclosed in FIG. 23 to FIG. 28B are not limited to such a method, but instead may stand alone as structures independent of the method.

FIG. 23 illustrates providing a donor carrier 100, in accordance with some embodiments. First, an intermediate structure similar to FIG. 2 is provided. In some embodiments, the intermediate structure includes an etch stop layer 102, a silicon channel layer 104, an interfacial layer 106, a high-k layer 108 and a gate layer 110 sequentially disposed on a substrate 101.

Thereafter, a bonding structure BS1 is formed on top of the gate layer 110. In some embodiments, the bonding structure BS1 is a bonding metal layer 113. The bonding metal layer 113 includes Ni, Sn, Au, Cu or a combination thereof. The bonding metal layer 113 has a thickness of about 10-100 nm (e.g., 40 nm). A donor carrier 100 is thus obtained. In some embodiments, the donor carrier 100 includes, from bottom to top, a substrate 101, an etch stop layer 102, a silicon channel layer 104, an interfacial layer 106, a high-k layer 108, a gate layer 110 and a bonding structure BS1.

FIG. 24 illustrates providing a device carrier 200, in accordance with some embodiments. First, an intermediate structure similar to FIG. 4 is provided, but the bonding structure BS2 is a bonding metal layer 213 instead of a bonding dielectric layer 212 of FIG. 4. The bonding metal layer 213 includes Ni, Sn, Au, Cu or a combination thereof. The bonding metal layer 213 has a thickness of about 10-100 nm (e.g., 40 nm). In some embodiments, the bonding metal layer 113 and the bonding metal layer 213 include the same material, such as copper. In some embodiments, the bonding metal layer 113 and the bonding metal layer 213 include different metallic materials. A device carrier 200 is thus obtained. In some embodiments, the device carrier 200 includes, from bottom to top, a substrate 202, a front-end of line (FEOL) 208, a back-end of line (BEOL) 210 and a bonding structure BS2. The BEOL 210 includes metal features embedded in dielectric layers DL. The metal features include metal lines and metal vias. In FIG. 24, four metal line levels are shown, inter-level metal vias are not shown, and top metal lines Mₓ are labelled for further illustration purpose. In some embodiments, the top metal lines Mₓ are exposed by the top dielectric layer DL, such that one or more of top metal lines Mₓ are in contact with bonding metal layer 213. The region B indicates a region where the metal feature may be present or not, depending on circuit functionality.

As shown in FIG. 24, the top surface of the bonding metal layer 113 of the donor carrier 100 and the top surface of the bonding metal layer 213 of the device carrier 200 may not be atomically flat. Specifically, the top surface of each of the bonding metal layer 113 and the bonding metal layer 213 may have a bump-like texture to promote bonding, as in an enlarged view at the left side of FIG. 24.

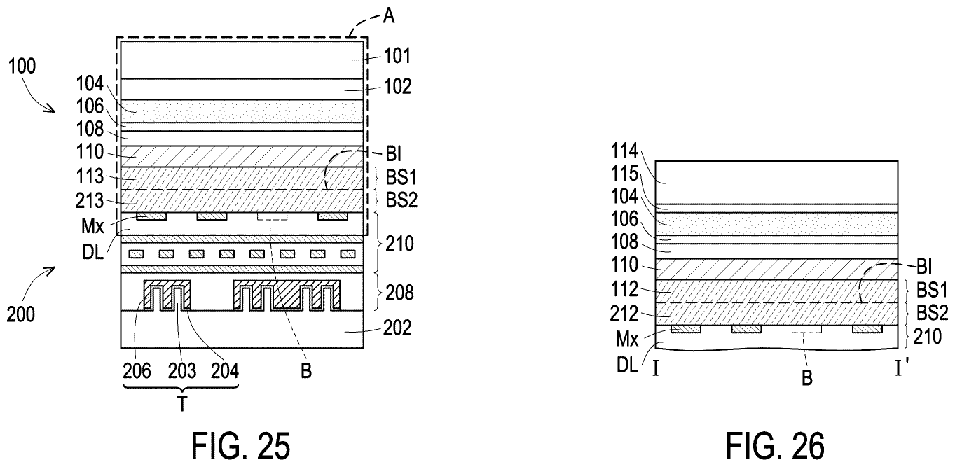

FIG. 24 and FIG. 25 illustrate bonding the donor carrier 100 to the device carrier 200, in accordance with some embodiments. In some embodiments, the donor carrier 100 is turned over and bonded to the device carrier 200 through the bonding structure BS1 (e.g., the bonding metal layer 113) and the bonding structure BS2 (e.g., the bonding metal layer 213). The bonding structure BS1 and the bonding structure BS2 are collectively constitute a “composite bonding structure”. The bonding interface BI between the bonding dielectric layer 112 and the bonding dielectric layer 212 may or may not be detectible. Such metal-to-metal bonding between metallic materials is referred to as a “eutectic bonding” in some examples. In some embodiments, a post-bond curing annealing is performed to improve bonding strength between the bonding structure BS1 and the bonding structure BS2. From here on, a local region A of a simplified stack will be shown for clarity.

FIG. 26 illustrates removing the substrate 101 and the etch stop layer 102, in accordance with some embodiments. Specifically, the substrate 101 and the etch stop layer 102 are sequentially removed from the donor carrier 100, and the silicon channel layer 104 is exposed.

FIG. 26 further illustrates forming an interfacial layer 115 and a dielectric layer 114, in accordance with some embodiments. The interfacial layer 115 is formed to passivate the top surface of the silicon channel layer 104. The interfacial layer 115 may be optional and may be omitted as needed.

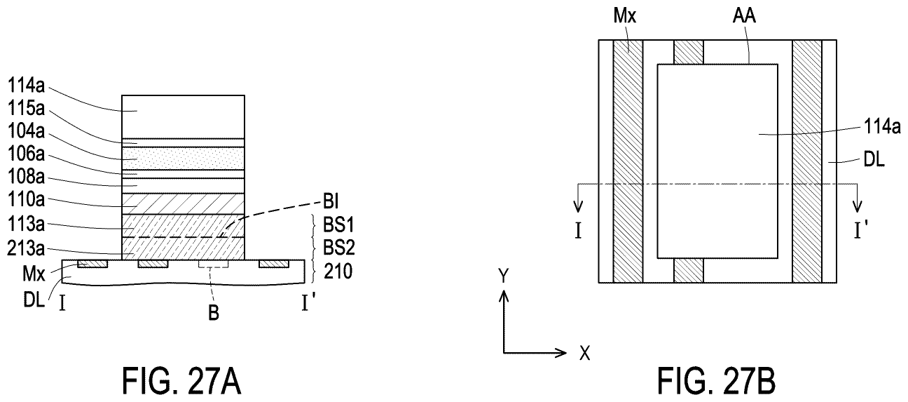

FIG. 27A and FIG. 27B illustrate forming a TFT stack, in accordance with some embodiments. FIG. 27A may be a cross-sectional view taken along the line I-I′ of the top view of FIG. 27B. As shown in FIG. 27A, a patterning process is performed to pattern the layered structure, so as to form a stack including, from bottom to top, a patterned bonding structure BS2, a patterned bonding structure BS1, a gate pattern 110a, a high-k pattern 108a, an interfacial pattern 106a, a silicon channel pattern 104a, an interfacial pattern 115a and a dielectric pattern 114a. The patterning process includes photolithography and etching processes. The dielectric pattern 114a acts as a hard mask to protect the underlying silicon channel pattern 104a. As shown in FIG. 27A, at least one top interconnect metal line Mₓ is in contact with the bonding metal of the bonding structure BS2. Some interconnect lines in the top interconnect metal level may be omitted depending on circuit functionality. Such an omitted line is denoted by B.

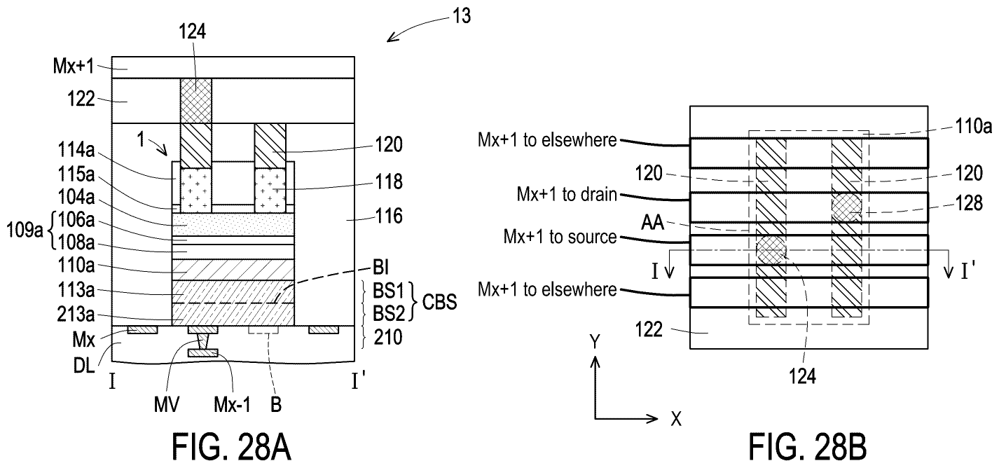

FIG. 28A and FIG. 28B illustrate patterning the TFT stack, in accordance with some embodiments. FIG. 28A may be a cross-sectional view taken along the line I-I′ of the top view of FIG. 28B. In some embodiments, operations similar to operations in FIGS. 13A-13B, 14A-14B, 15A-15B, 16A-16B, 17A-17B and 18A-18B are performed, so as to form a dielectric layer 116 around the stack, epitaxial layers 118 landed on the silicon channel pattern 104a, metal patterns 120 landed on the epitaxial layers 118, a dielectric layer 122 disposed over the dielectric layer 116, and metal vias 124 penetrating through the dielectric layer 122 and landed on the metal patterns 120. In some embodiments, as shown in FIG. 28B, the stack has a dimension of about 45 nm to 40 um in the X-direction and a dimension of about 40 nm to 40 um in the Y-direction. One or more TFTs can be formed in one active area AA along the X-direction.

FIG. 28A and FIG. 28B further illustrate forming metal lines over the TFT stack, in accordance with some embodiments. By arranging the positions of vias 124, different metal lines Mₓ₊₁ are formed over and electrically connected to different TFT terminals, or another metal features. As shown in FIG. 28B, one metal line Mₓ₊₁ is electrically connected to a source of the TFT, one metal line Mₓ₊₁ is electrically connected to a drain of the TFT, and two metal lines Mₓ₊₁ are electrically connected to other metal features. An integrated circuit structure 13 of some embodiments of the disclosure is thus completed. Specifically, the integrated circuit structure 13 is basically built in the same way as the integrated circuit structure 10, but there is no via from Mₓ₊₁ to the gate pattern. The “metal gate reveal” operations (e.g., FIGS. 10A-11C) are skipped. Instead, there may be a metal via MV between the top metal line Mₓ and an underlying metal line Mₓ₋₁ to control the gate of the TFT from the FEOL 208.

In the above embodiments, a donor carrier including at least one TFT device and a device carrier including at least one FET device are bonded by a metal eutectic bonding, but the disclosure is not limited thereto. In other embodiments, a donor carrier including at least one TFT device and a device carrier including at least one FET device may be bonded through a hybrid bonding comprising a dielectric-to-dielectric bonding and a metal-to-metal bonding.

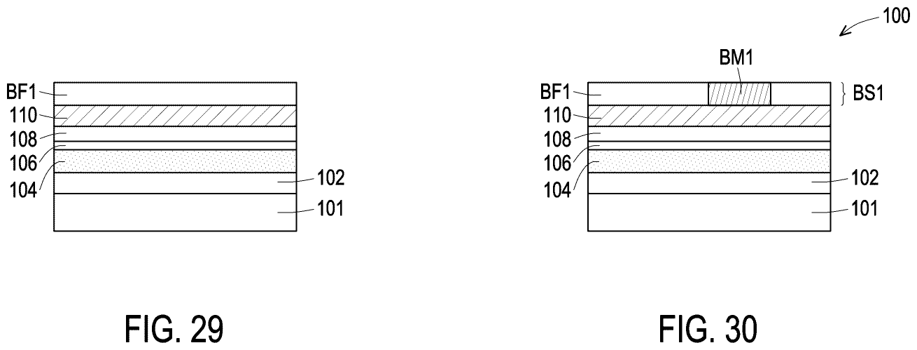

FIGS. 29, 30, 31, 32A, 32B, 32C, 33A, 33B, 34, 35A, 35B and 36 illustrate varying views of manufacturing an integrated circuit structure in accordance with some embodiments. It is understood that the disclosure is not limited by the method described below. Additional operations can be provided before, during, and/or after the method and some of the operations described below can be replaced or eliminated, for additional embodiments of the methods. Although FIG. 29 to FIG. 36 are described in relation to a method, it is appreciated that the structures disclosed in FIG. 29 to FIG. 36 are not limited to such a method, but instead may stand alone as structures independent of the method.

FIG. 29 and FIG. 30 illustrate providing a donor carrier 100, in accordance with some embodiments. First, an intermediate structure similar to FIG. 2 is provided. In some embodiments, the intermediate structure includes an etch stop layer 102, a silicon channel layer 104, an interfacial layer 106, a high-k layer 108 and a gate layer 110 sequentially disposed on a substrate 101. Thereafter, a bonding structure BS1 is formed on top of the gate layer 110. In some embodiments, as shown in FIG. 29, a dielectric bonding film BF1 is formed on the gate layer 110. The dielectric bonding film BF1 includes silicon oxide, silicon nitride, SiCN, or a combination thereof. The dielectric bonding film BF1 has a thickness of about 10-100 nm (e.g., 40 nm). Thereafter, as shown in FIG. 30, at least one metal bonding feature BM1 is formed in the dielectric bonding film BF1. A patterning process is performed to the dielectric bonding film BF1 to form at least one opening that exposes the gate layer 110, and the opening is then filled with a metal bonding feature BM1. The width of the metal bonding feature BM1 ranges from about 40-200 nm. The metal bonding feature BM1 includes Ni, Sn, Au, Cu or a combination thereof. In some embodiments, the metal bonding feature BM1 includes a metal barrier between a bonding metal and the dielectric bonding film BF1. The metal barrier includes Ti, TiN, Ta, TaN, or a combination thereof, and has a thickness of about 1-4 nm. A donor carrier 100 is thus obtained. In some embodiments, the donor carrier 100 includes, from bottom to top, a substrate 101, an etch stop layer 102, a silicon channel layer 104, an interfacial layer 106, a high-k layer 108, a gate layer 110 and a bonding structure BS1.

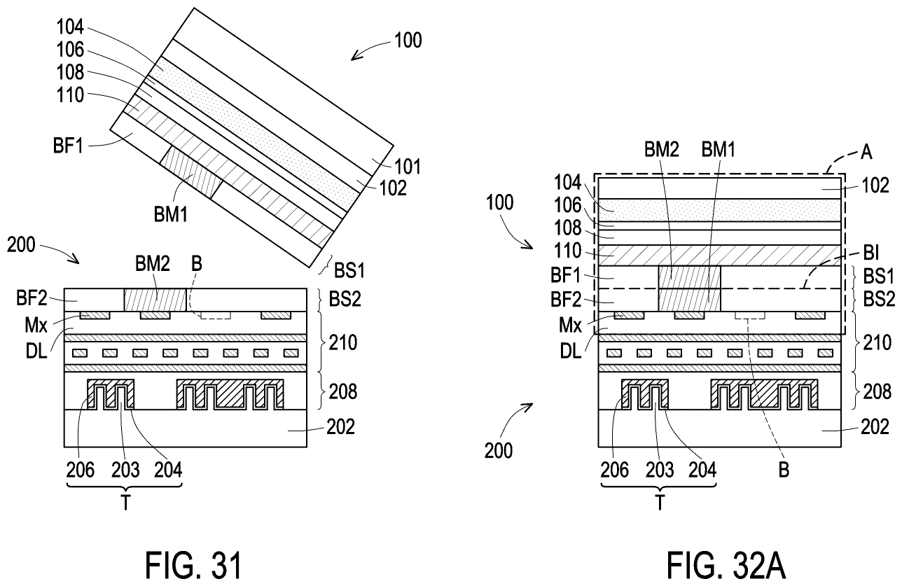

FIG. 31 illustrates providing a device carrier 200, in accordance with some embodiments. First, an intermediate structure similar to FIG. 4 is provided, in which the bonding structure BS2 includes at least one metal bonding feature BM2 embedded in a dielectric bonding film BF2, instead of the bonding dielectric layer 212 of FIG. 4. The dielectric bonding film BF2 includes silicon oxide, silicon nitride, SiCN, or a combination thereof. The dielectric bonding film BF2 has a thickness of about 10-100 nm (e.g., 40 nm). The metal bonding feature BM2 includes Ni, Sn, Au, Cu or a combination thereof. The width of the metal bonding feature BM2 ranges from about 40-200 nm.

In some embodiments, the dielectric bonding film BF1 and the dielectric bonding film BF2 include the same material, such as silicon oxide. In some embodiments, the dielectric bonding film BF1 and the dielectric bonding film BF2 include different materials, one of which is silicon oxide and the other is silicon nitride. In some embodiments, the metal bonding feature BM1 and the metal bonding feature BM2 include the same material, such as copper. In some embodiments, the metal bonding feature BM1 and the metal bonding feature BM2 include different metallic materials. A device carrier 200 is thus obtained. In some embodiments, the device carrier 200 includes, from bottom to top, a substrate 202, a front-end of line (FEOL) 208, a back-end of line (BEOL) 210 and a bonding structure BS2.

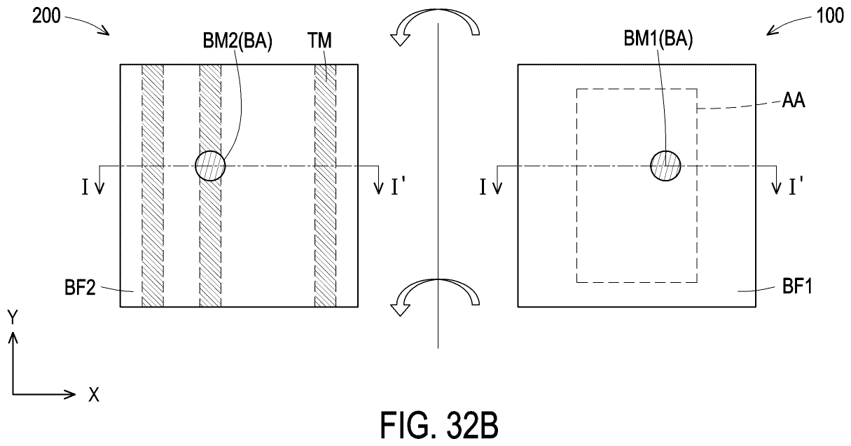

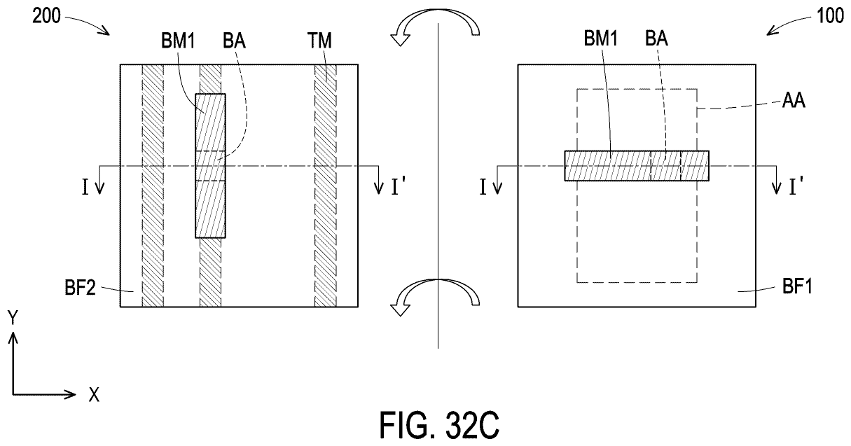

FIG. 32A illustrates bonding the donor carrier 100 to the device carrier 200 from a cross-sectional view, in accordance with some embodiments. In some embodiments, the donor carrier 100 is turned over and bonded to the device carrier 200 through the bonding structure BS1 and the bonding structure BS2. The bonding interface BI between the bonding structure BS1 and the bonding structure BS2 may or may not be detectible. The bonding structure BS1 and the bonding structure BS2 are collectively constitute a “composite bonding structure”. Specifically, the dielectric bonding film BF1 is bonded to the dielectric bonding film BF2, and the metal bonding feature BM1 is bonded to the metal bonding feature BM2. Such bonding including a dielectric-to-dielectric bonding and metal-to-metal bonding is referred to as a “hybrid bonding” in some examples. In some embodiments, a post-bond curing annealing is performed to improve bonding strength between the bonding structure BS1 and the bonding structure BS2. From here on, a local region A of a simplified stack will be shown for clarity.

FIG. 32B illustrates bonding the donor carrier 100 to the device carrier 200 from a top view, in accordance with some embodiments. The donor carrier 100 is turned over and bonded to the device carrier 200, so the metal bonding feature BM1 is overlapped with the metal bonding feature BM2. In this embodiment, the size or the top-view area of the metal bonding feature BM1 is substantially equal to the size or the top-view area of the metal bonding feature BM2. In these embodiments, the bonding arca BA between the metal bonding feature BM1 and the metal bonding feature BM2 is substantially the same as the size of the metal bonding feature BM1 or the metal bonding feature BM2. Each of the metal bonding feature BM1 and the metal bonding feature BM2 has a circle-like shape, a square shape or a rectangular shape.

FIG. 32C illustrates bonding the donor carrier 100 to the device carrier 200 from a top view, in accordance with some embodiments. The donor carrier 100 is turned over and bonded to the device carrier 200, so the metal bonding feature BM1 is overlapped with the metal bonding feature BM2. In this embodiment, the metal bonding feature BM1 and the metal bonding feature BM2 have strip-like shapes perpendicular to each other, and the bonding area BA is the intersection area between the metal bonding feature BM1 and the metal bonding feature BM2.

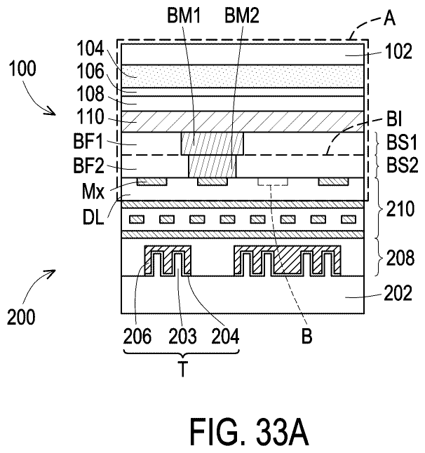

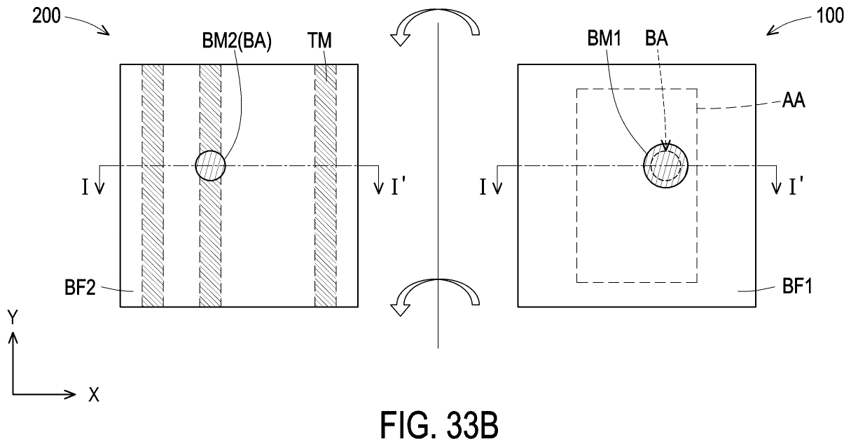

FIG. 33A illustrates bonding the donor carrier 100 to the device carrier 200 from a cross-sectional view, in accordance with other embodiments. FIG. 33B illustrates bonding the donor carrier 100 to the device carrier 200 from a top view, in accordance with some embodiments. The donor carrier 100 is turned over and bonded to the device carrier 200, so the metal bonding feature BM1 is overlapped with the metal bonding feature BM2. In this embodiment, the size or the top-view area of the metal bonding feature BM1 is different from (e.g., greater than) the size or the top-view area of the metal bonding feature BM2, so as to provide more process tolerance for misalignment. In these embodiments, the bonding area BA between the metal bonding feature BM1 and the metal bonding feature BM2 is substantially the same as the size of the metal bonding feature BM2.

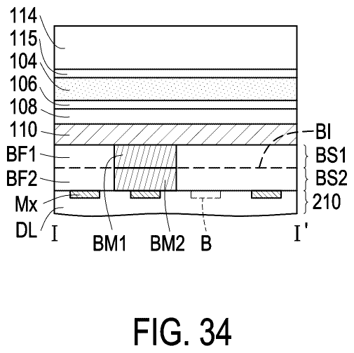

FIG. 34 illustrates removing the substrate 101 and the etch stop layer 102, in accordance with some embodiments. Specifically, the substrate 101 and the etch stop layer 102 are removed from the donor carrier 100, and the silicon channel layer 104 is exposed.

FIG. 34 further illustrates forming an interfacial layer 115 and a dielectric layer 114, in accordance with some embodiments. The interfacial layer 115 is formed to passivate the top surface of the silicon channel layer 104. The interfacial layer 115 may be optional and may be omitted as needed.

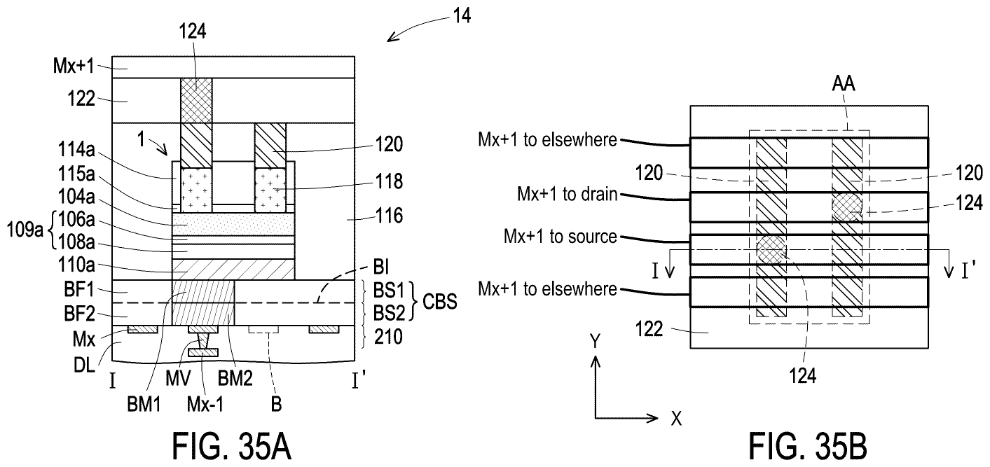

FIG. 35A and FIG. 35B illustrate forming a TFT stack, in accordance with some embodiments. FIG. 35A may be a cross-sectional view taken along the line I-I′ of the top view of FIG. 35B. As shown in FIG. 35A, a patterning process is performed to pattern the layered structure, so as to form a stack including, from bottom to top, a gate pattern 110a, a high-k pattern 108a, an interfacial pattern 106a, a silicon channel pattern 104a, an interfacial pattern 115a and a dielectric pattern 114a. The patterning process includes photolithography and etching processes. The dielectric pattern 114a acts as a hard mask to protect the underlying silicon channel pattern 104a. Thereafter, operations similar to operations in FIGS. 13A-13B, 14A-14B, 15A-15B, 16A-16B, 17A-17B and 18A-18B are performed, so as to form a dielectric layer 116 around the stack, epitaxial layers 118 landed on the silicon channel pattern 104a, metal patterns 120 landed on the epitaxial layers 118, a dielectric layer 122 disposed over the dielectric layer 116, and metal vias 124 penetrating through the dielectric layer 122 and landed on the metal patterns 120. In some embodiments, as shown in FIG. 35B, the stack has a dimension of about 45 nm to 40 um in the X-direction and a dimension of about 40 nm to 40 um in the Y-direction. One or more TFTs can be formed in one active area AA along the X-direction.

FIG. 35A and FIG. 35B further illustrate forming metal lines over the TFT stack, in accordance with some embodiments. By arranging the positions of vias 124, different metal lines Mₓ₊₁ are formed over and electrically connected to different TFT terminals, or another metal features. As shown in FIG. 35B, one metal line Mₓ₊₁ is electrically connected to a source of the TFT, one metal line Mₓ₊₁ is electrically connected to a drain of the TFT, and two metal lines Mₓ₊₁ are electrically connected to other metal features. An integrated circuit structure 14 of some embodiments of the disclosure is thus completed. Specifically, the integrated circuit structure 14 is basically built in the same way as the integrated circuit structure 10, but there is no via from Mₓ₊₁ to the gate pattern. The “metal gate reveal” operations (e.g., FIG. 10A-11C) are skipped. Instead, there may be a metal via MV between the top metal line Mₓ and an underlying metal line Mₓ₋₁ to control the gate from the FEOL 208.

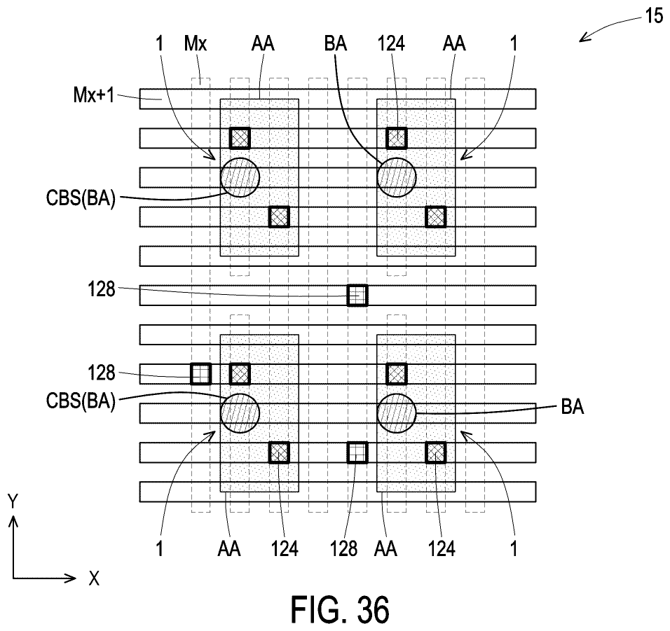

FIG. 36 illustrates an integrated circuit structure of other embodiments of the disclosure. In some embodiments, from a top view, part (10-90%, e.g., 50%) of wafer area is covered by active areas AA. For example, multiple active areas AA are illustrated in FIG. 36. In some embodiments, multiple metal lines Mₓ of the device carrier extend in a direction (e.g., Y-direction), and multiple metal lines Mₓ₊₁ of the donor carrier extend in another direction (e.g., X-direction) different from the first direction. The donor carrier is bonded to the device carrier through a hybrid bonding, in which the metal-to-metal bonding area BA is shown in each active arca AA. In FIG. 36, multiple TFT devices 1 of the donor carrier are respectively disposed in the multiple active areas AA and between the corresponding metal lines Mₓ and the metal lines Mₓ₊₁. In some embodiments, each active area AA contains at least one source and at least one drain, which are electrically connected to metal lines Mₓ₊₁ through multiple metal vias 124. In some embodiments, multiple metal vias 128 are provided to electrically connect the metal lines Mₓ to the corresponding metal lines Mₓ₊₁. An integrated circuit structure 15 is thus obtained. Specifically, the integrated circuit structure 15 is in an array form, and each active area AA may have an integrated circuit structure 14.

According to some embodiments of the disclosure, a method of forming integrated circuit structure includes following operations. A donor carrier 100 is provided, and the donor carrier 100 includes, from bottom to top, an etch stop layer 102, a silicon channel layer 104, a gate dielectric layer 109, a gate layer 110 and a first bonding structure BS1 on a first substrate 101. A device carrier 200 is provided, and the device carrier 200 includes, from bottom top, a device layer 208, an interconnect structure 210, a second bonding structure BS1 on a second substrate 202. The donor carrier 100 is flipped over and bonded to the device carrier 200 through the first bonding structure BS1 and the second bonding structure BS2. The etch stop layer 102 and the first substrate 101 are removed from the donor carrier 100. A first dielectric layer 114 is formed on the silicon channel layer 104. The dielectric layer 114, the silicon channel layer 104, the gate dielectric layer 109 and the gate layer 110 are patterned to form a TFT stack including, from bottom to top, a gate pattern 110a, a gate dielectric pattern 109a, a silicon channel pattern 104a and a first dielectric pattern 114a. At least one source contact 118/120 and at least one drain contact 118/120 are formed separately on the silicon channel pattern 104a. In some embodiments, each of the first bonding structure BS1 and the second bonding structure BS2 is a dielectric bonding layer 112/212, a metal bonding layer 113/213, or at least one metal bonding feature BM1/BM2 embedded in a dielectric bonding film BF1/BF2. In some embodiments, a width of the gate pattern 110a is substantially the same as a width of the silicon channel pattern 104a.

In the above embodiments, the silicon channel and the gate pattern have substantially the same dimension, but the disclosure is not limited thereto. In other embodiments, the dimension of the silicon channel may be different from (e.g., greater than) the dimension of the gate pattern. The dimension may include a width, a length or an area. Smaller gate width may decrease the gate-induced drain leakage and therefore improve the device reliability.

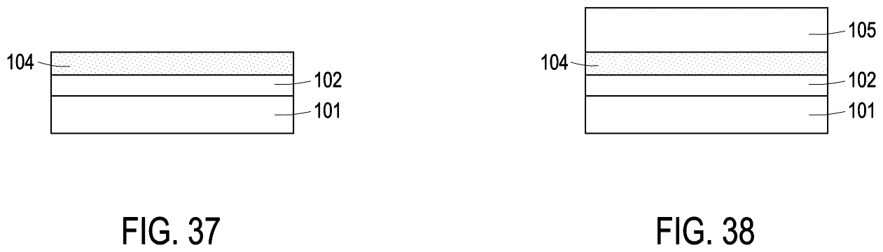

FIGS. 37, 38, 39A, 39B, 40, 41, 42, 43, 44, 45A, 45B, 46A, 46B, 47A, 47B, 48A, 48B, 48C, 49A, 49B, 49C, 50A, 50B, 51A, 51B, 52A, 52B, 53A, 53B, 54A, 54B, 55A, 55B, 56A, 56B, 56C, 57A, 57B, 57C, 58A and 58B illustrate varying views of manufacturing an integrated circuit structure in accordance with some embodiments. It is understood that the disclosure is not limited by the method described below. Additional operations can be provided before, during, and/or after the method and some of the operations described below can be replaced or eliminated, for additional embodiments of the methods. Although FIG. 37 to FIG. 58B are described in relation to a method, it is appreciated that the structures disclosed in FIG. 37 to FIG. 58B are not limited to such a method, but instead may stand alone as structures independent of the method.

FIG. 37 to FIG. 41 illustrate providing a donor carrier 100, in accordance with some embodiments. First, as shown in FIG. 37, an etch stop layer 102 and a silicon channel layer 104 are sequentially formed on the substrate 101. Thereafter, a dielectric layer 105 is formed on the silicon channel layer 104, as shown in FIG. 38. The dielectric layer 105 includes silicon oxide and has a thickness of about 20-200 nm (e.g., 100 nm). Other dielectric materials may be applicable. The dielectric layer 105 may be formed by ALD or CVD.

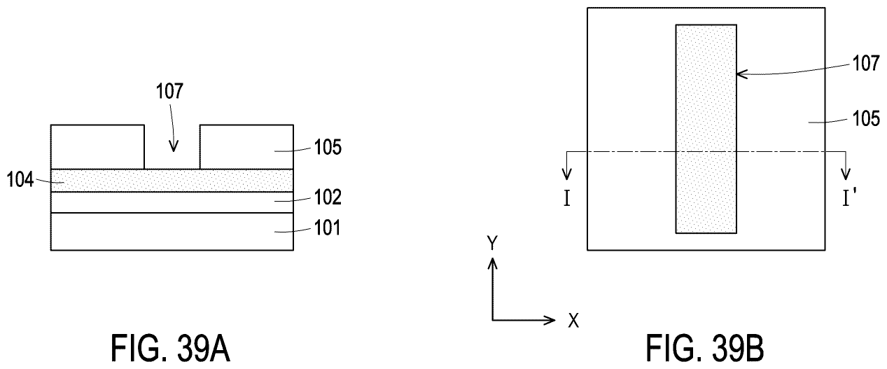

FIG. 39A and FIG. 39B illustrate forming an opening 107 in the dielectric layer 105, in accordance with some embodiments. FIG. 39A may be a cross-sectional view taken along the line I-I′ of the top view of FIG. 39B. As shown in FIG. 39B, a patterning process is performed to the dielectric layer 105, so as to form an opening 107 exposing the silicon channel layer 104. The patterning process includes photolithography and etching processes. As shown in FIG. 39B, the opening 107 has a strip-like shape. The opening 107 has a dimension of about 20 nm to 200 nm (e.g., 30-35 nm) in X-direction and a dimension of about 80 nm to 45 um in Y-direction. In some embodiments, the dimension of the opening 107 is larger than the dimension of an active area in one direction (e.g., Y-direction). The opening 107 is referred to as a “gate opening” in some examples.

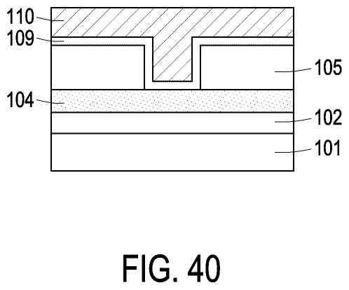

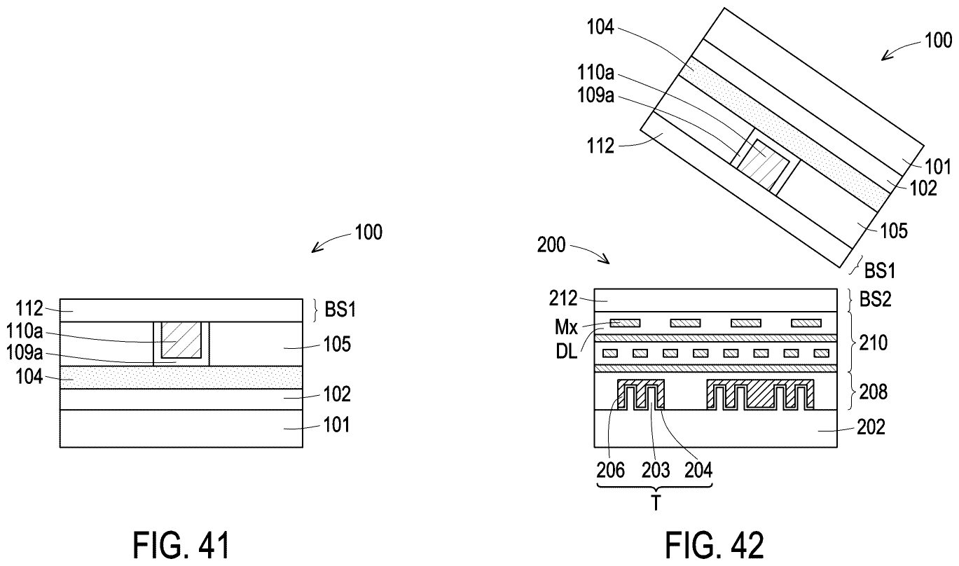

FIG. 40 and FIG. 41 illustrate forming a gate dielectric layer 109 and a gate layer 110 in the opening 107 of the dielectric layer 105, in accordance with some embodiments.

As shown in FIG. 40, a gate dielectric layer 109 is conformally formed on the dielectric layer 105 along the sidewall and bottom of the opening 107. The gate dielectric layer may include an interfacial layer and a high-k layer. In some embodiments, the interfacial layer includes silicon oxide and has a thickness of about 1-8 nm (e.g., 2 nm). The interfacial layer may be a chemical oxide, formed from a chemical reaction at the silicon surface, e.g., with ozone (O₃) in combination with HF and/or HCl. The interfacial layer may be a thermal oxide, by rapid thermal annealing (RTA) in an oxygen-containing ambient, or by in situ steam generation (ISSG). The interfacial layer 115 may be a deposited oxide formed by atomic layer deposition (ALD) or chemical vapor deposition (CVD). The chemical oxide (<100° C.) and ALD oxide (<300° C.) may be preferred in the disclosure owing to their low process temperature. The interfacial layer is formed to passivate the top surface of the silicon channel layer 104. Thereafter, the high-k layer is formed on the interfacial layer. In some embodiments, the high-k layer includes a dielectric having a dielectric constant greater than 10 and has a thickness of about 1-8 nm (e.g., 2 nm). The high-k layer may be formed by ALD. The high-k layer includes HfO₂, Al₂O₃, ZrO₂, HfZrOₓ, HfAlOₓ, HfSiOₓ, La₂O₃, TiO₂ or a combination thereof. After the high-k layer is formed, an annealing process may be performed in hydrogen-containing, oxygen-containing or nitrogen-containing ambient to cure bulk defects in the high-k layer. The interfacial layer may be optional and may be omitted as needed.

Thereafter, a gate layer 110 is formed over the gate dielectric layer 109 and completely fills the opening 107. In some embodiments, the gate layer 110 includes Ti, TiN, Ta, TaN, TiAl, W, Cu, or a combination thereof and has a thickness of about 4-40 nm (e.g., 20 nm). For example, the gate layer 110 may be a layered stack, e.g., TiN/TiAl/TaN, or TiN/W. For example, the gate layer 110 may include a work function metal (e.g., TiN) and a filling metal (e.g., W). The gate layer 110 may be formed by ALD or PVD.

As shown in FIG. 41, the gate dielectric layer 109 and the gate layer 110 outside the opening 107 are removed by a planarization process, so as to form a gate dielectric pattern 109a and a gate pattern 110a in the opening 107. Specifically, the gate dielectric pattern 109a is disposed between the gate pattern 110a and the dielectric layer 105 and between the gate pattern 110a and the silicon channel layer 104. In some embodiments, the surface of the gate dielectric pattern 109a is flush with the surface of the gate pattern 110a and the surface of the dielectric layer 105.

Afterwards, a bonding structure BS1 is formed on top of the gate pattern 110a. Specifically, the bonding structure BS1 is formed over the dielectric layer 105 and in contact with the gate dielectric pattern 109a and the gate pattern 110a. In some embodiments, the bonding structure BS1 is a bonding dielectric layer 112. The bonding dielectric layer 112 includes silicon oxide, silicon nitride, SiCN, or a combination thereof. The bonding dielectric layer 112 has a thickness of about 10-100 nm (e.g., 40 nm). A donor carrier 100 is thus obtained.

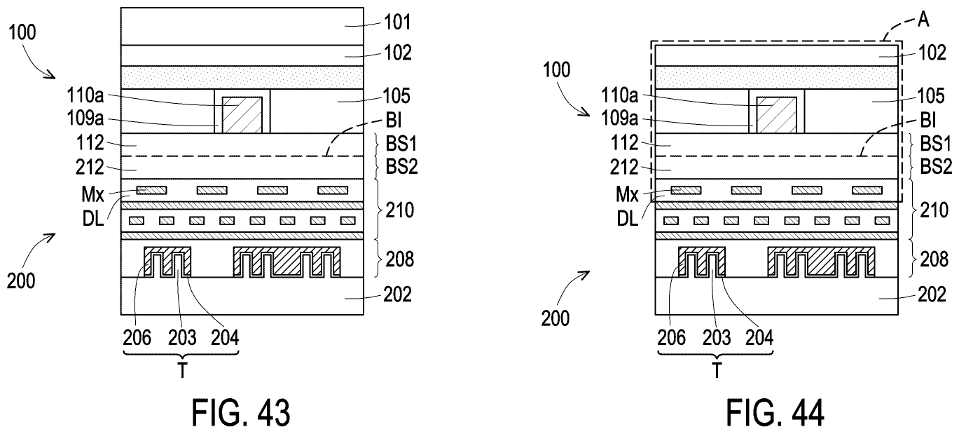

FIG. 42 and FIG. 43 illustrate providing a device carrier 200 and bonding the device 200 to the donor carrier 100, in accordance with some embodiments. Specifically, the substrate 101 and the etch stop layer 102 are sequentially removed from the donor carrier 100, and the silicon channel layer 104 is exposed. The operations of FIG. 42 and FIG. 43 are similar to those described in FIG. 4 and FIG. 5, so the details are not iterated herein.

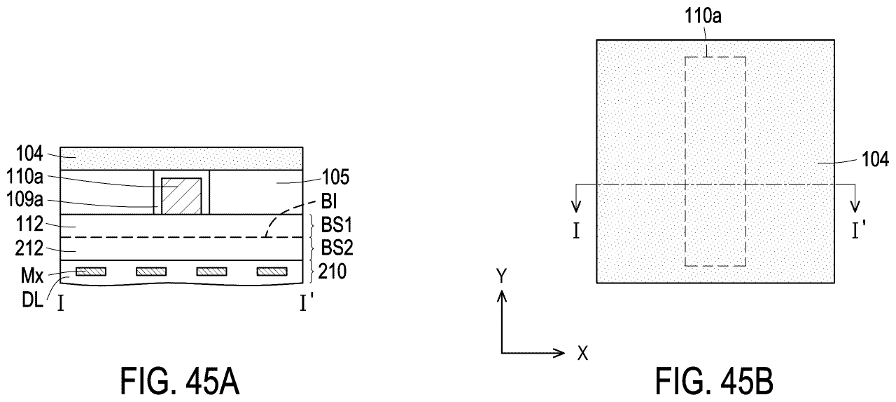

FIG. 44 to FIG. 45B illustrate removing the substrate 101 and the etch stop layer 104 from the donor carrier 100, in accordance with some embodiments. Specifically, the substrate 101 and the etch stop layer 102 are sequentially removed from the donor carrier 100, and the silicon channel layer 104 is exposed. The operations of FIG. 44 to FIG. 45B are similar to those described in FIG. 6 to FIG. 7B, so the details are not iterated herein.

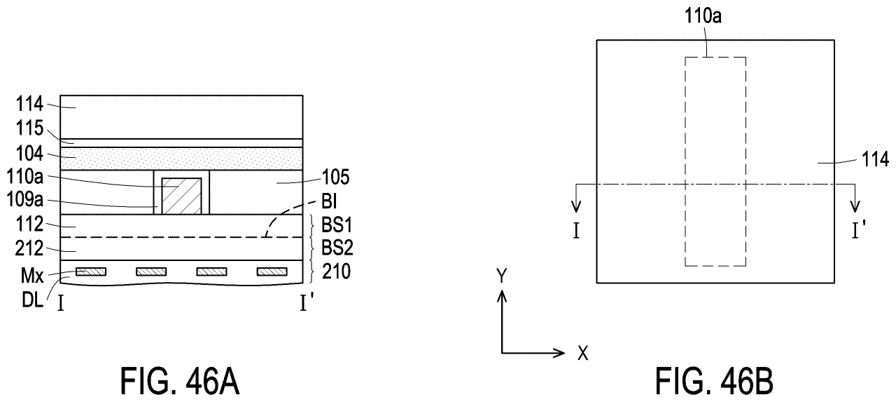

FIG. 46A to FIG. 46B illustrate forming an interfacial layer 115 and a dielectric layer 114 on the silicon channel layer 104, in accordance with some embodiments. The interfacial layer 115 is formed to passivate the top surface of the silicon channel layer 104. The interfacial layer 115 may be optional and may be omitted as needed. The operations of 46A to FIG. 46B are similar to those described in FIG. 8A and FIG. 8B, so the details are not iterated herein.

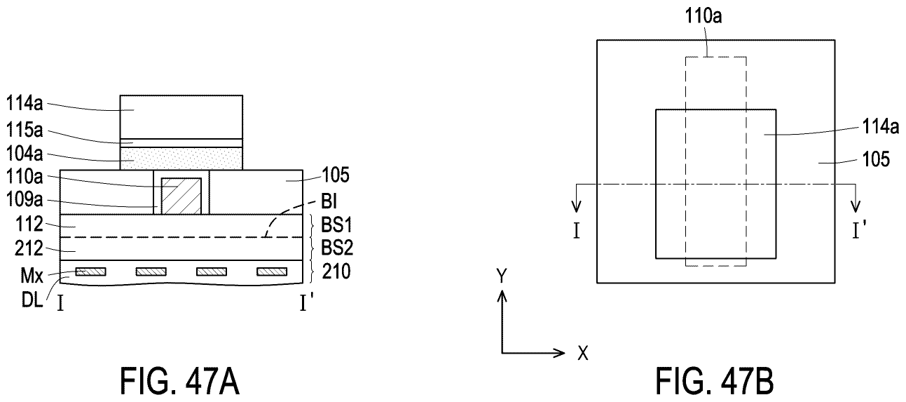

FIG. 47A and FIG. 47B illustrate forming a TFT stack, in accordance with some embodiments. FIG. 47A may be a cross-sectional view taken along the line I-I′ of the top view of FIG. 47B. As shown in FIG. 47A, a patterning process is performed to pattern the layered structure, so as to form a stack including a silicon channel pattern 104a disposed on the dielectric layer 105 and the gate dielectric pattern 109a, an interfacial pattern 115a disposed on the silicon channel pattern 104a, and a dielectric pattern 114a disposed on the interfacial pattern 115a. The patterning process includes photolithography and etching processes. The dielectric pattern 114a acts as a hard mask to protect the underlying silicon channel pattern 104a. In some embodiments, as shown in FIG. 47B, the stack has a dimension of about 45 nm to 40 um in X-direction and a dimension of about 40 nm to 40 um in Y-direction. One or more TFTs can be formed in one active area along the X-direction. In some embodiments, as shown in FIG. 47B, the TFT stack extends beyond the gate metal 110a in the Y-direction by a distance d1. d1 has a dimension of about 10 nm to 40 nm.

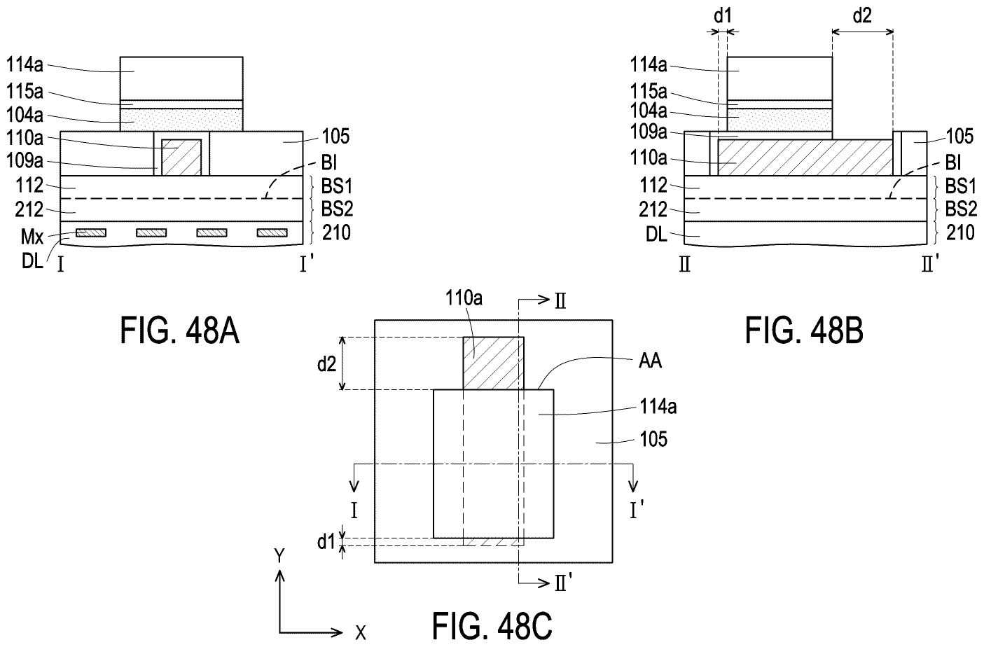

FIG. 48A, FIG. 48B and FIG. 48C illustrate patterning the TFT stack, in accordance with some embodiments. FIG. 48A may be a cross-sectional view taken along the line I-I′ of the top view of FIG. 48C, and FIG. 48B may be a cross-sectional view taken along the line II-II′ of the top view of FIG. 48C. As shown in FIG. 48B, a patterning process is performed to pattern the stack, until a portion of the gate pattern 110a is exposed. The patterning process includes photolithography and etching processes. Specifically, the dielectric pattern 114a, the interfacial pattern 115a, the silicon channel pattern 104a, the gate dielectric pattern 109a are sequentially patterned and partially removed, until a portion of the gate pattern 110a is exposed. In some embodiments, as shown in FIG. 48B, the first sidewall (e.g., left sidewall) of the gate pattern 110a is protruded from the first sidewall (e.g., left sidewall) of the silicon channel pattern 104a by a first distance d1, while the second sidewall (e.g., right sidewall) of the gate pattern 110a is protruded from the second sidewall (e.g., right sidewall) of the silicon channel pattern 104a by a second distance d2 greater than the first distance d1. In some embodiments, as shown in FIG. 48C, the first distance d1 has a dimension of about 10 nm to 40 nm in Y-direction, and the second distance d2 has a dimension of about 20 nm to 100 nm in Y-direction.

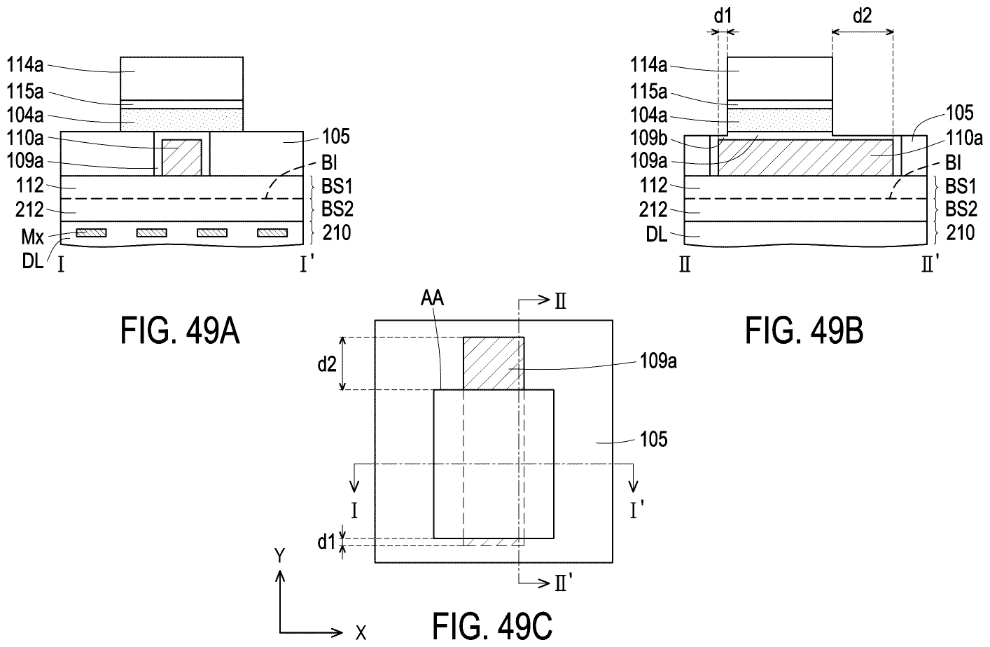

Alternatively, the patterning process of FIG. 48A to FIG. 48C may not etch through the gate dielectric pattern 109a, so a thin gate dielectric 109b remains on the gate pattern 110a, as shown in FIG. 49A, FIG. 49B and FIG. 49C. The thin high-k pattern 109b may cover and protect the underlying gate pattern 110a from being damaged in the subsequent processes.

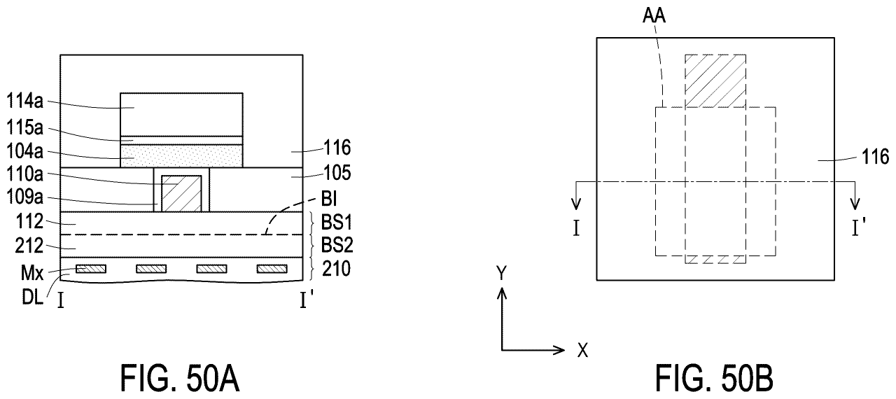

FIG. 50A and FIG. 50B illustrate forming a dielectric layer 116, in accordance with some embodiments. Specifically, a dielectric layer 116 is formed to cover the patterned TFT stack. The operations of 50A to FIG. 50B are similar to those described in FIG. 12A and FIG. 12B, so the details are not iterated herein.

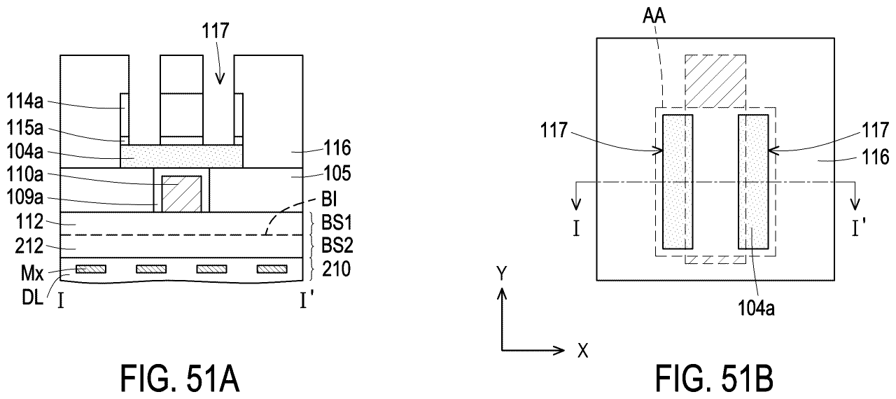

FIG. 51A and FIG. 51B illustrate forming openings 117 in the patterned TFT stack, in accordance with some embodiments. The operations of 51A to FIG. 51B are similar to those described in FIG. 13A and FIG. 13B, so the details are not iterated herein.

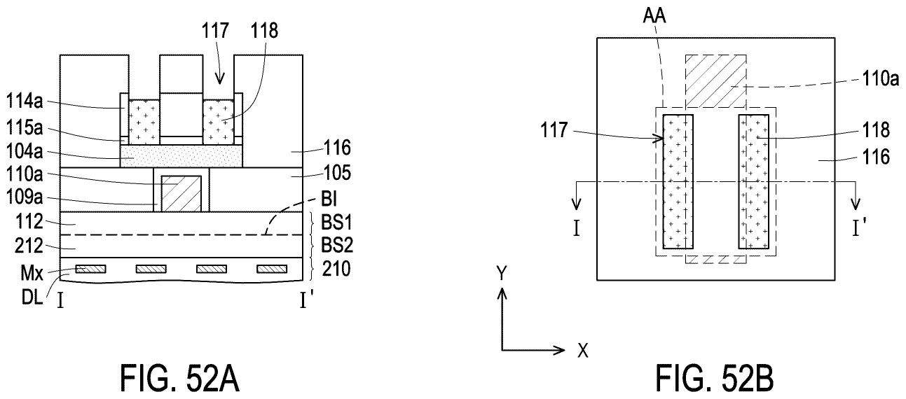

FIG. 52A and FIG. 52B illustrate forming epitaxial layers 118, in accordance with some embodiments. The operations of 52A to FIG. 52B are similar to those described in FIG. 14A and FIG. 14B, so the details are not iterated herein.

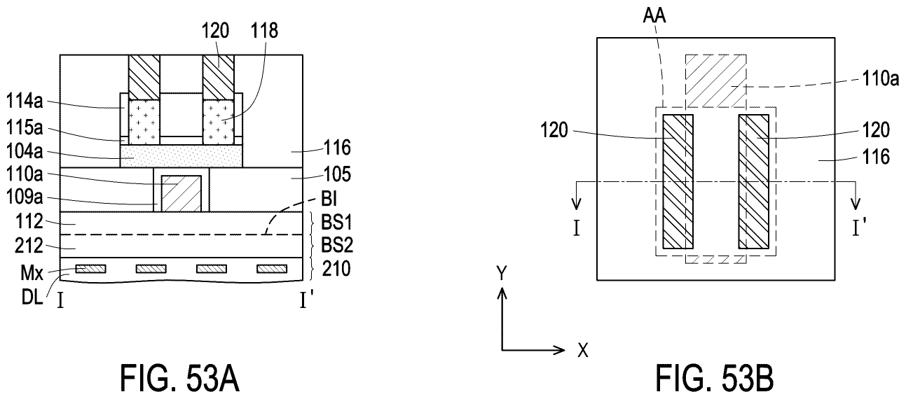

FIG. 53A and FIG. 53B illustrate forming metal patterns 120, in accordance with some embodiments. The operations of 53A to FIG. 53B are similar to those described in FIG. 15A and FIG. 15B, so the details are not iterated herein.

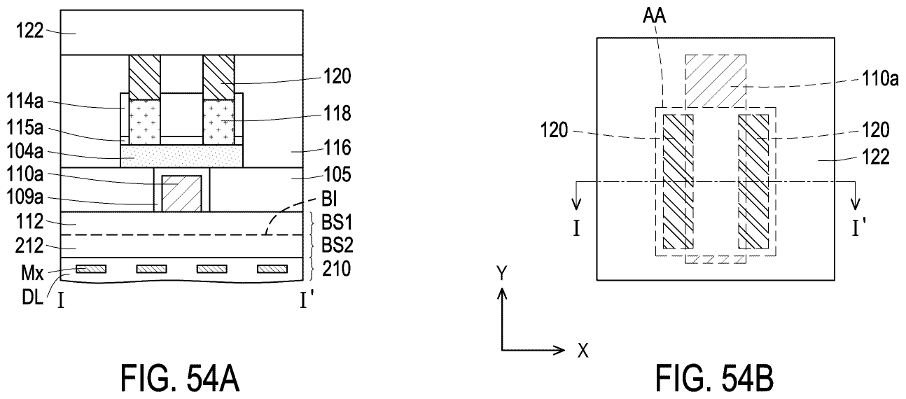

FIG. 54A and FIG. 54B illustrate forming a dielectric layer 122, in accordance with some embodiments. The operations of 54A to FIG. 54B are similar to those described in FIG. 16A and FIG. 16B, so the details are not iterated herein.

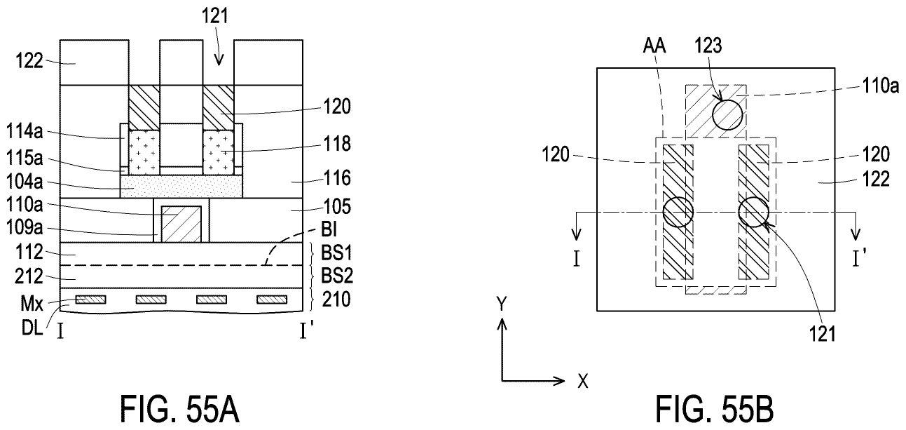

FIG. 55A and FIG. 55B illustrate forming openings 121 and 123 in the dielectric layer 122, in accordance with some embodiments. The operations of 55A to FIG. 55B are similar to those described in FIG. 17A and FIG. 17B, so the details are not iterated herein.

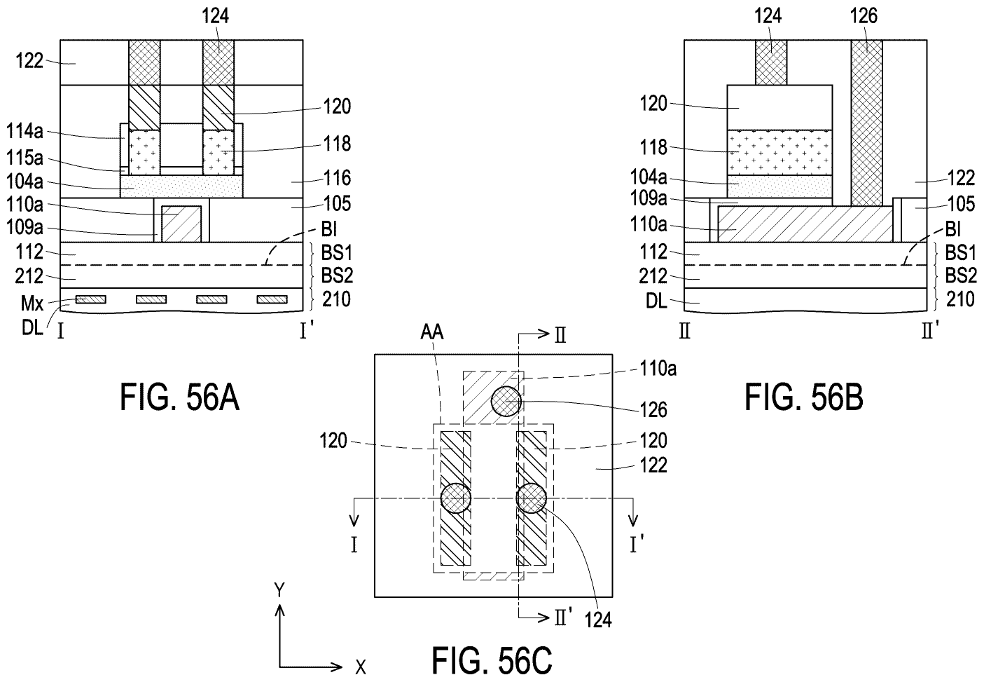

FIG. 56A, FIG. 56A and FIG. 56C illustrate forming metal vias 124 and 126, in accordance with some embodiments. The operations of 56A to FIG. 56C are similar to those described in FIG. 18A to FIG. 18C, so the details are not iterated herein.

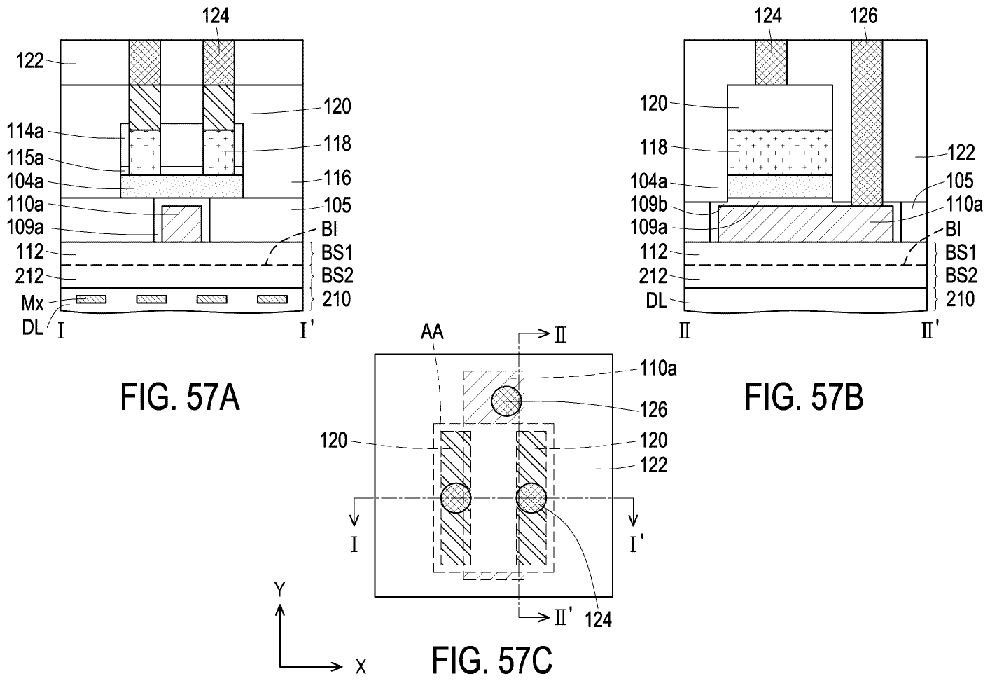

FIG. 57A, FIG. 57A and FIG. 57C illustrate other embodiments of FIG. 56A, FIG. 56A and FIG. 56C. FIG. 57A may be a cross-sectional view taken along the line I-I′ of the top view of FIG. 57C, and FIG. 57B may be a cross-sectional view taken along the line II-II′ of the top view of FIG. 57C. Specifically, in the structure of FIG. 57A, FIG. 57B and FIG. 57C, a thin gate dielectric pattern 109b remains on the gate pattern 110, and the metal via 126 penetrates through the thin gate dielectric pattern 109b and is landed on the gate pattern 110a.

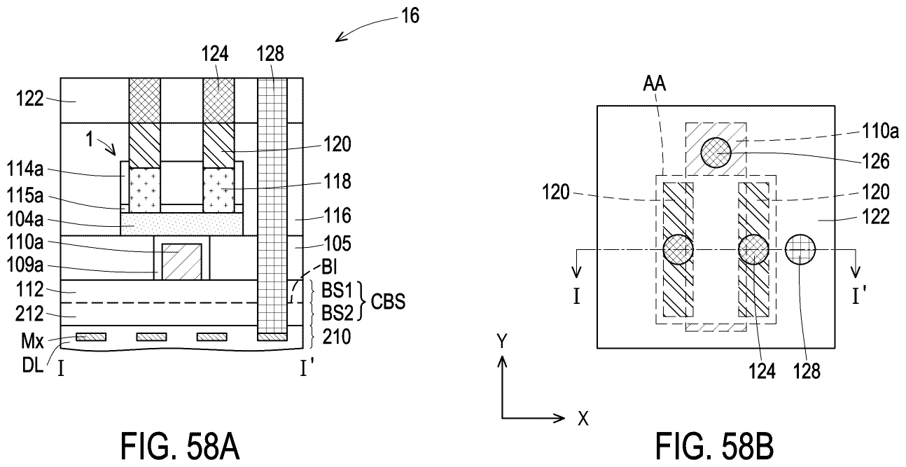

FIG. 58A and FIG. 58B illustrate forming a deep via 128, in accordance with some embodiments. The operations of 58A to FIG. 58B are similar to those described in FIG. 20A to FIG. 20B, so the details are not iterated herein. An integrated circuit structure 16 of some embodiments of the disclosure is thus completed.

In the above embodiments, a donor carrier including at least one TFT device and a device carrier including at least one FET device are bonded by a dielectric fusion bonding, but the disclosure is not limited thereto. In other embodiments, a donor carrier including at least one TFT device and a device carrier including at least one FET device may be bonded through a metal eutectic bonding.

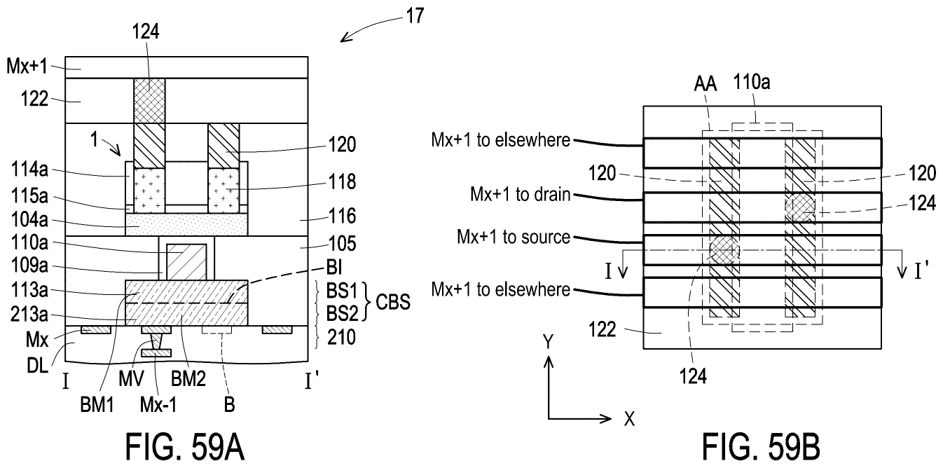

FIG. 59A and FIG. 59B illustrate an integrated circuit structure of other embodiments of the disclosure. FIG. 59A may be a cross-sectional view taken along the line I-I′ of the top view of FIG. 59B.

The integrated circuit structure 17 of FIG. 59A is similar to the integrated circuit structure 13 of FIG. 28A, and the difference between them lies in the configuration and forming method of a gate dielectric layer 109a and a gate pattern 110a. Specifically, in the integrated circuit structure 17 of FIG. 59A, the width of the gate pattern 110a is less than the width of the silicon channel pattern 104a in the X-direction, and the gate dielectric layer 109a is formed not only between the silicon channel pattern 104a and the gate pattern 110a but also along the sidewall of the gate pattern 110a. Smaller gate width may decrease the gate-induced drain leakage and therefore improve the device reliability.

In the above embodiments, a donor carrier including at least one TFT device and a device carrier including at least one FET device are bonded by a metal eutectic bonding, but the disclosure is not limited thereto. In other embodiments, a donor carrier including at least one TFT device and a device carrier including at least one FET device may be bonded through a hybrid bonding including a dielectric-to-dielectric bonding and a metal-to-metal bonding.

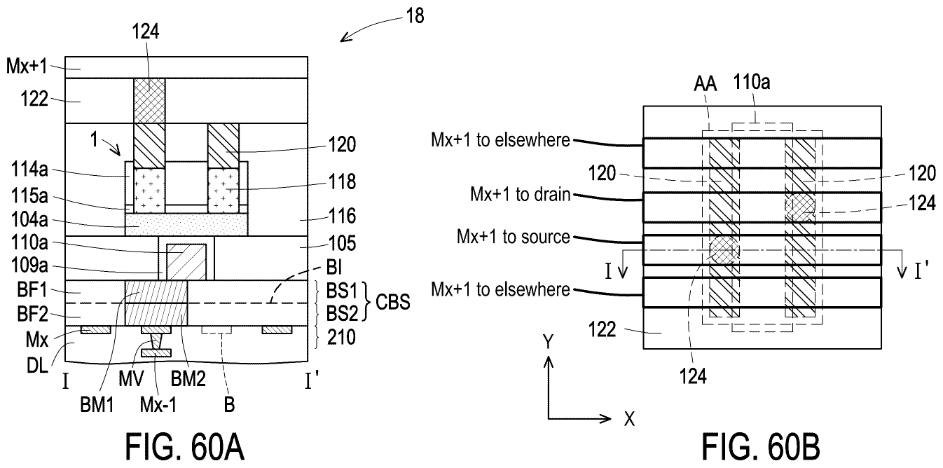

FIG. 60A and FIG. 60B illustrate an integrated circuit structure of other embodiments of the disclosure. FIG. 60A may be a cross-sectional view taken along the line I-I′ of the top view of FIG. 60B.

The integrated circuit structure 18 of FIG. 60A is similar to the integrated circuit structure 14 of FIG. 35A, and the difference between them lies in the configuration and forming method of a gate dielectric layer 109a and a gate pattern 110a. Specifically, in the integrated circuit structure 18 of FIG. 60A, the width of the gate pattern 110a is less than the width of the silicon channel pattern 104a in the X-direction, and the gate dielectric layer 109a is formed not only between the silicon channel pattern 104a and the gate pattern 110a but also along the sidewall of the gate pattern 110a. Smaller gate width may decrease the gate-induced drain leakage and therefore improve the device reliability.

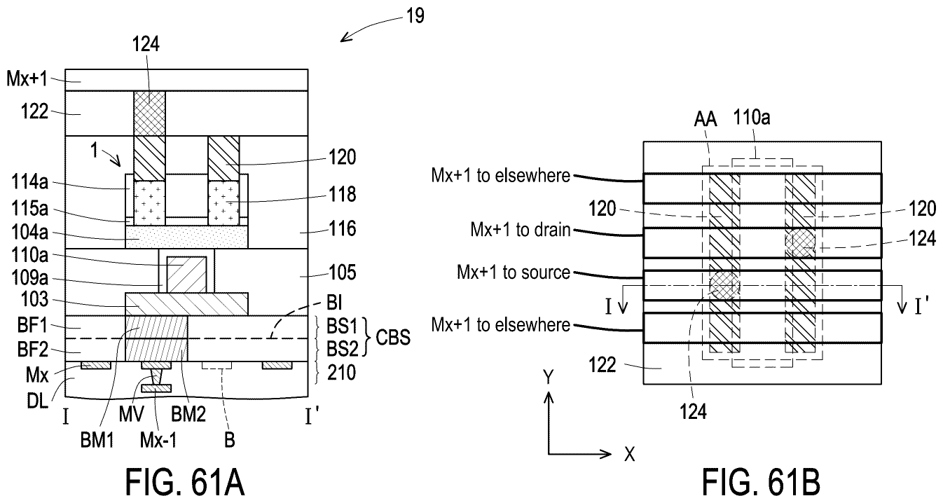

FIG. 61A and FIG. 61B illustrate an integrated circuit structure of other embodiments of the disclosure. FIG. 61A may be a cross-sectional view taken along the line I-I′ of the top view of FIG. 61B.

The integrated circuit structure 19 of FIG. 61A is similar to the integrated circuit structure 18 of FIG. 60A, and the difference between them lies in that, the integrated circuit structure 19 of FIG. 61A further includes additional metal pattern 103 disposed between the gate pattern 110a and the metal bonding feature BM1. The width of the additional metal pattern 103 is greater than the width of the overlying gate pattern 110a and the width of the underlying metal bonding feature BM1, so as to provide more process tolerance for misalignment.

According to some embodiments of the disclosure, a method of forming integrated circuit structures includes following operations. A donor carrier 100 is provided, and the donor carrier 100 includes, from bottom to top, an etch stop layer 102, a silicon channel layer 104, a gate dielectric pattern 109a, a gate pattern 110a and a first bonding structure BS1 on a first substrate 101. A device carrier 200 is provided, and the device carrier 200 includes, from bottom top, a device layer 208, an interconnect structure 210, a second bonding structure BS1 on a second substrate 202. The donor carrier 100 is flipped over and bonded to the device carrier 200 through the first bonding structure BS1 and the second bonding structure BS2. The etch stop layer 102 and the first substrate 101 are removed from the donor carrier 100. A first dielectric layer 114 is formed on the silicon channel layer 104. At least the dielectric layer 114 and the silicon channel layer 104 are subjected to a patterning process, so as to form a gate structure including, from bottom to top, a gate pattern 110a, a gate dielectric pattern 109a, a silicon channel pattern 104a and a first dielectric pattern 114a. At least one source contact 118/120 and at least one drain contact 118/120 are formed separately on the silicon channel pattern 104a. In some embodiments, each of the first bonding structure BS1 and the second bonding structure BS2 is a dielectric bonding layer 112/212, a metal bonding layer 113/213, or at least one metal bonding feature BM1/BM2 embedded in a dielectric bonding film BF1/BF2. In some embodiments, a width of the gate pattern 110a is less than a width of the silicon channel pattern 104a.

The integrated circuit structures are illustrated below with reference to FIGS. 20A, 21A, 22A, 28A, 35A, 36, 58A, 59A, 60A, 61A and other figures.

According to some embodiments of the disclosure, each of integrated circuit structures 10-19 includes a donor carrier 100 and a device carrier 200 bonded to each other. The donor carrier 100 includes a first bonding structure BS1, a gate pattern 104a disposed on the first bonding structure, a gate dielectric pattern 109a disposed on the gate pattern, a silicon channel pattern 104a disposed on the gate dielectric pattern, and at least one source contact 118/120 and at least one drain contact 118/120 disposed separately on the silicon channel pattern. The device carrier 200 includes a device layer 208, an interconnect structure 210 disposed on the device layer, and a second bonding structure BS2 disposed on the interconnect structure. The donor carrier 100 is bonded to the device carrier 200 through the first bonding structure BS1 and the second bonding structure BS2.

In some embodiments, each of the first bonding structure BS1 and the second bonding structure BS2 is a dielectric bonding layer 112/212. In some embodiments, a deep via 128 is formed to penetrate through the dielectric bonding layers and is landed on a top metal line Mₓ of the interconnect structure 210.

In some embodiments, each of the first bonding structure BS1 and the second bonding structure BS2 is a metal bonding layer 113/213. In some embodiments, the metal bonding layer 113 of the first bonding structure BS1 is in contact with the gate pattern 110a. In some embodiments, the metal bonding layer 213 of the second bonding structure BS2 is in contact with a top metal line Mₓ of the interconnect structure 210.

In some embodiments, each of the first bonding structure BS1 and the second bonding structure BS2 includes at least one metal bonding feature BM1/BM2 embedded in a dielectric bonding film BF1/BF2. In some embodiments, the metal bonding feature BM1 of the first bonding structure BS1 is in contact with the gate pattern 110a. In some embodiments, the metal bonding feature BM2 of the second bonding structure BS2 is in contact with a top metal line Mₓ of the interconnect structure 210.

In some embodiments, in each of the integrated circuit structures 10-15, a width of the gate pattern 110a is substantially the same as a width of the silicon channel pattern 104a. However, the disclosure is not limited thereto. In other embodiments, in each of the integrated circuit structures 16-19, a width of the gate pattern 110a is less than a width of the silicon channel pattern 104a.

According to some embodiments of the disclosure, each of integrated circuit structures 10-19 includes a lower interconnect structure 210, an upper interconnect structure Mₓ₊₁, a composite bonding structure CBS and a thin film transistor device 1. The lower interconnect structure 210 is disposed over a device layer 208. The upper interconnect structure is disposed over the lower interconnect structure. The composite bonding structure CBS is disposed between the lower interconnect structure 210 and the upper interconnect structure Mₓ₊₁. The thin film transistor device 1 is disposed between the composite bonding structure CBS and the upper interconnect structure Mₓ₊₁ and electrically connected to the lower interconnect structure 210 and the upper interconnect structure Mₓ₊₁. The thin film transistor device 1 includes a gate pattern 110a disposed over and in contact with the composite bonding structure CBS, a gate dielectric pattern 109a disposed on the gate pattern, a silicon channel pattern 104a disposed on the gate dielectric pattern, and at least one source contact 118/120 and at least one drain contact 118/120 disposed separately on the silicon channel pattern.

In some embodiments, the composite bonding structure CBS includes a first bonding structure BS1 and a second bonding structure BS2 bonded to each other, and each of the first bonding structure BS1 and the second bonding structure BS2 is a dielectric bonding layer 112/212, a metal bonding layer 113/213, or at least one metal bonding feature BM1/BM2 embedded in a dielectric bonding film BF1/BF2.

In some embodiments, the metal bonding features of the first bonding structure and the second bonding structure are shaped as dots overlapped with each other, as shown in FIGS. 32B and 33B. In some embodiments, the metal bonding features of the first bonding structure and the second bonding structure are shaped as strips perpendicular to each other as shown in FIG. 32C.

In some embodiments, in each of the integrated circuit structures 10-15, a width of the gate pattern 110a is substantially the same as a width of the silicon channel pattern 104a. However, the disclosure is not limited thereto. In other embodiments, in each of the integrated circuit structures 16-19, a width of the gate pattern 110a is less than a width of the silicon channel pattern 104a.

In view of the above, the present disclosure is directed to integrated circuit structures and manufacturing methods thereof. In the integrated circuit structure of the disclosure, a silicon thin film transistor device (TFT) and a field effect transistor (FET) are manufactured on different substrates and then bonded together. By such method, a back-gated silicon thin film transistor device can be formed with a smaller device footprint and can be easily manufactured in a back-end of line (BEOL). In the present disclosure, the gate width of the TFT can be adjusted to provide more process flexibility.

According to some embodiments of the disclosure, an integrated circuit structure includes a donor carrier and a device carrier bonded to each other. The donor carrier includes a first bonding structure, a gate pattern disposed on the first bonding structure, a gate dielectric pattern disposed on the gate pattern, a silicon channel pattern disposed on the gate dielectric pattern, and at least one source contact and at least one drain contact disposed separately on the silicon channel pattern. The device carrier includes a device layer, an interconnect structure disposed on the device layer, and a second bonding structure disposed on the interconnect structure. The donor carrier is bonded to the device carrier through the first bonding structure and the second bonding structure.

According to some embodiments of the disclosure, an integrated circuit structure includes a lower interconnect structure, an upper interconnect structure, a composite bonding structure and a thin film transistor device. The lower interconnect structure is disposed over a device layer. The upper interconnect structure is disposed over the lower interconnect structure. The composite bonding structure is disposed between the lower interconnect structure and the upper interconnect structure. The thin film transistor device is disposed between the composite bonding structure and the upper interconnect structure and electrically connected to the lower interconnect structure and the upper interconnect structure. The thin film transistor device includes a gate pattern disposed over and in contact with the composite bonding structure, a gate dielectric pattern disposed on the gate pattern, a silicon channel pattern disposed on the gate dielectric pattern, and at least one source contact and at least one drain contact disposed separately on the silicon channel pattern.

According to some embodiments of the disclosure, a method of forming integrated circuit structure includes following operations. A donor carrier is provided, and the donor carrier includes, from bottom to top, an etch stop layer, a silicon channel layer, a gate dielectric layer, a gate layer and a first bonding structure on a first substrate. A device carrier is provided, and the device carrier includes, from bottom top, a device layer, an interconnect structure, a second bonding structure on a second substrate. The donor carrier is flipped over and bonded to the device donor through the first bonding structure and the second bonding structure. The etch stop layer and the first substrate are removed from the donor carrier. A first dielectric layer is formed on the silicon channel layer. The dielectric layer, the silicon channel layer, the gate dielectric layer and the gate layer are patterned to form a gate structure including, from bottom to top, a gate pattern, a gate dielectric pattern, a silicon channel pattern and a first dielectric pattern. At least one source contact and at least one drain contact are formed separately on the silicon channel pattern.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC devices, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit structure, comprising:
a donor carrier comprising:
a first bonding structure;
a gate pattern disposed on the first bonding structure;
a gate dielectric pattern disposed on the gate pattern;
a silicon channel pattern disposed on the gate dielectric pattern; and
at least one source contact and at least one drain contact disposed separately on the silicon channel pattern; and
a device carrier comprising:
a device layer;
an interconnect structure disposed on the device layer; and
a second bonding structure disposed on the interconnect structure,
wherein the donor carrier is bonded to the device carrier through the first bonding structure and the second bonding structure.

2. The integrated circuit structure of claim 1, wherein each of the first bonding structure and the second bonding structure is a dielectric bonding layer.

3. The integrated circuit structure of claim 2, further comprising a deep via that penetrates through the dielectric bonding films and is landed on a top metal line of the interconnect structure.

4. The integrated circuit structure of claim 1, wherein each of the first bonding structure and the second bonding structure is a metal bonding layer.

5. The integrated circuit structure of claim 4, wherein the metal bonding film of the first bonding structure is in contact with the gate pattern.

6. The integrated circuit structure of claim 4, wherein the metal bonding film of the second bonding structure is in contact with a top metal line of the interconnect structure.

7. The integrated circuit structure of claim 1, wherein each of the first bonding structure and the second bonding structure comprises at least one metal bonding feature embedded in a dielectric bonding film.

8. The integrated circuit structure of claim 7, wherein the metal bonding feature of the first bonding structure is in contact with the gate pattern.

9. The integrated circuit structure of claim 7, wherein the metal bonding feature of the second bonding structure is in contact with a top metal line of the interconnect structure.

10. The integrated circuit structure of claim 1, wherein a width of the gate pattern is substantially the same as a width of the silicon channel pattern.

11. The integrated circuit structure of claim 1, wherein a width of the gate pattern is less than a width of the silicon channel pattern.

12. The integrated circuit structure of claim 1, wherein each of the source contact and the drain contact comprises an epitaxial material, a metallic material or a combination thereof.

13. An integrated circuit structure, comprising:
a lower interconnect structure disposed over a device layer;
an upper interconnect structure disposed over the lower interconnect structure;
a composite bonding structure disposed between the lower interconnect structure and the upper interconnect structure; and
a thin film transistor device disposed between the composite bonding structure and the upper interconnect structure and electrically connected to the lower interconnect structure and the upper interconnect structure,
wherein the thin film transistor device comprises:
a gate pattern disposed over and in contact with the composite bonding structure;
a gate dielectric pattern disposed on the gate pattern;
a silicon channel pattern disposed on the gate dielectric pattern; and
at least one source contact and at least one drain contact disposed separately on the silicon channel pattern.

14. The integrated circuit structure of claim 13, wherein the composite bonding structure comprises a first bonding structure and a second bonding structure bonded to each other, and each of the first bonding structure and the second bonding structure is a dielectric bonding layer, a metal bonding layer, or at least one metal bonding feature embedded in a dielectric bonding film.

15. The integrated circuit structure of claim 13, wherein each of the first bonding structure and the second bonding structure comprises at least one metal bonding feature embedded in a dielectric bonding film, and the metal bonding features of the first bonding structure and the second bonding structure are shaped as dots overlapped with each other.

16. The integrated circuit structure of claim 13, wherein each of the first bonding structure and the second bonding structure comprises at least one metal bonding feature embedded in a dielectric bonding film, and the metal bonding features of the first bonding structure and the second bonding structure are shaped as strips perpendicular to each other.

17. The integrated circuit structure of claim 13, wherein a width of the gate pattern is substantially the same as a width of the silicon channel pattern.

18. The integrated circuit structure of claim 13, wherein a width of the gate pattern is less than a width of the silicon channel pattern.

19. A method of forming integrated circuit structure, comprising:
providing a donor carrier comprising, from bottom to top, an etch stop layer, a silicon channel layer, a gate dielectric layer, a gate layer and a first bonding structure on a first substrate;
providing a device carrier comprising, from bottom top, a device layer, an interconnect structure, a second bonding structure on a second substrate;
flipping over the donor carrier and bonding the donor carrier to the device layer through the first bonding structure and the second bonding structure;
removing the etch stop layer and the first substrate from the donor carrier;
forming a first dielectric layer on the silicon channel layer;
patterning the dielectric layer, the silicon channel layer, the gate dielectric layer and the gate layer to form a gate structure comprising, from bottom to top, a gate pattern, a gate dielectric pattern, a silicon channel pattern and a first dielectric pattern; and
forming at least one source contact and at least one drain contact separately on the silicon channel pattern.

20. The method of claim 19, wherein each of the first bonding structure and the second bonding structure is a dielectric bonding layer, a metal bonding layer, or at least one metal bonding feature embedded in a dielectric bonding film.
